(19) United States
(12) Patent Application Publication
(10) Pub. No.: US 2024/0243549 A1
(43) Pub. Date: Jul. 18, 2024

(54) DISTRIBUTED REFLECTOR LASER DIODE AND METHOD FOR MANUFACTURING THE SAME

(71) Applicant: ELECTRONICS AND TELECOMMUNICATIONS RESEARCH INSTITUTE, Daejeon (KR)

(72) Inventors: Su Hwan OH, Daejeon (KR); Kisoo KIM, Daejeon (KR); Hongseung KIM, Daejeon (KR)

(73) Assignee: ELECTRONICS AND TELECOMMUNICATIONS RESEARCH INSTITUTE, Daejeon (KR)

(21) Appl. No.: 18/413,680

(22) Filed: Jan. 16, 2024

(30) Foreign Application Priority Data
Jan. 16, 2023 (KR) 10-2023-0005953
Jan. 16, 2023 (KR) 10-2023-0005981
Mar. 14, 2023 (KR) 10-2023-0033393
Sep. 14, 2023 (KR) 10-2023-0122729
Jan. 3, 2024 (KR) 10-2024-0000677
Jan. 10, 2024 (KR) 10-2024-0004296
Jan. 10, 2024 (KR) 10-2024-0004397

(51) Int. Cl. H01S 5/125; H01S 5/024; H01S 5/042; H01S 5/34

(52) U.S. Cl. CPC H01S 5/125; H01S 5/02453; H01S 5/0421; H01S 5/04256; H01S 5/3407

(57) ABSTRACT

Disclosed are a distributed reflector laser diode and a method for manufacturing the same. The diode includes a substrate including a DFB region and a DBR region contacting the DFB region, an active layer on the substrate of the DFB region, a first lattice on the active layer, a second lattice provided on the substrate of the DBR region and thicker than the first lattice, an upper clad layer on the first lattice and the second lattice, an ohmic contact layer on the upper clad layer of the DFB region, an upper electrode on the ohmic contact layer, an insulating layer on the clad layer of the DBR region, and a heater layer on the insulating layer.

### CROSS-REFERENCE TO RELATED APPLICATIONS

This U.S. non-provisional patent application claims priority under 35 U.S.C. § 119 of Korean Patent Application Nos. 10-2023-0005953, filed on Jan. 16, 2023, 10-2023-0005981, filed on Jan. 16, 2023, 10-2023-0033393, filed on Mar. 14, 2023, 10-2023-0122729, filed on Sep. 14, 2023, and 10-2024-0000677, filed on Jan. 3, 2024, 10-2024-0004296, filed on Jan. 10, 2024, 10-2024-0004397, filed on Jan. 10, 2024, the entire contents of which are hereby incorporated by reference.

### BACKGROUND

The present disclosure herein relates to a laser diode and a method for manufacturing the same, and more particularly, to a distributed reflector laser diode and a method for manufacturing the same.

Lidar technology is evolving into a next-generation FMCW scheme for overcoming technical limitations of a first-generation ToF scheme, and a high-performance laser light source of a transmitter, which is a core component of an FMCW lidar, is being developed. FMCW light sources have a low linewidth and employ optical communication devices of 1.55 μm band. Laser diodes with an external cavity laser structure and single integrated structure are mainly used as FMCW light sources, and one of characteristics of such laser is a linewidth of 1 MHz or less, and the range and precision of FMCW light sources improve as the linewidth decreases.

### SUMMARY

The present disclosure provides a distributed reflector laser diode having a small length and low linewidth.

An embodiment of the inventive concept provides a distributed reflector laser diode including: a substrate including a distributed feed-back (DFB) region and a distributed Bragg reflection (DBR) region contacting the DFB region; an active layer on the substrate of the DFB region; a first lattice on the active layer; a second lattice provided on the substrate of the DBR region and thicker than the first lattice; an upper clad layer on the first lattice and the second lattice; an ohmic contact layer on the upper clad layer of the DFB region; an upper electrode on the ohmic contact layer; an insulating layer on the clad layer of the DBR region; and a heater layer on the insulating layer.

In an embodiment, the distributed reflector laser diode may further include a lower spacer layer provided between the active layer and the substrate.

In an embodiment, the distributed reflector laser diode may further include a lower clad layer provided between the lower spacer layer and the substrate.

In an embodiment, the lower clad layer may have the same thickness as that of the second lattice.

In an embodiment, the distributed reflector laser diode may further include an upper spacer layer provided between the first lattice and the active layer.

In an embodiment, the upper spacer layer may have the same thickness as that of the lower spacer layer.

In an embodiment, the lower spacer layer, the upper spacer layer, and the upper clad layer each may include indium phosphide (InP).

In an embodiment, the active layer may include a multi quantum well (MQW) active layer.

In an embodiment, the upper clad layer may include a first trench between the DFB region and the DBR region and a second trench on an outer periphery of the heater layer.

In an embodiment, the substrate may further include a semiconductor optical amplifier region on one side of the DFB region facing the DBR region.

In an embodiment of the inventive concept, a distributed reflector laser diode includes: a substrate including a distributed feed-back (DFB) region and a distributed Bragg reflection (DBR) region contacting the DFB region; a lower clad layer on the substrate of the DFB region; an active layer on the lower clad layer; a first lattice on the active layer; a second lattice on the substrate of the DFB region; an upper clad layer between the first lattice and the second lattice; an upper electrode on the upper clad layer of the DFB region; and a heater layer on the upper clad layer of the DBR region.

In an embodiment, the first lattice may include: a first lower lattice in the lower clad layer; and a first upper lattice in the upper clad layer.

In an embodiment, the first lattice may further include a first intermediate lattice in the active layer between the first lower lattice and the first upper lattice.

In an embodiment, the second lattice may include: a second lower lattice adjacent to the first lower lattice; a second intermediate lattice provided on the second lower lattice and adjacent to the first intermediate lattice; and a second upper lattice provided on the second intermediate lattice and adjacent to the first upper lattice.

In an embodiment, the first lower lattice, the first intermediate lattice, and the first upper lattice may be discontinuously arranged in a direction perpendicular to the substrate, and the second lower lattice, the second intermediate lattice, and the second upper lattice may be continuously arranged in a direction perpendicular to the substrate.

In an embodiment of the inventive concept, a method for manufacturing a distributed reflector laser diode includes: sequentially forming a lower clad layer, a lower spacer layer, an active layer, an upper spacer layer, a first lattice layer, and a first cap layer on a substrate including a distributed feed-back (DFB) region and a distributed Bragg reflection (DBR) region contacting the DFB region; exposing the lower spacer layer by removing the active layer, the upper spacer layer, the first lattice layer, and the first cap layer from the DBR region; forming a first lattice by partially removing the first cap layer, the upper spacer layer, and the first lattice layer of the DFB region; forming a second lattice by partially removing the lower clad layer of the DBR region; forming an upper clad layer on the first lattice and the second lattice; forming an ohmic contact layer and an upper electrode on the upper clad layer of the DFB region; and forming an insulating layer and a heater layer on the upper clad layer of the DBR region.

In an embodiment, the first lattice may be formed through an etching process in which a first photoresist pattern and a first hard mask film are used as an etching mask.

In an embodiment, the method may further include forming a second hard mask film on the first photoresist pattern and the first hard mask film of the DFB region.

In an embodiment, the second lattice may be formed through an etching process of the lower clad layer using the first photoresist pattern, the first hard mask film, and the second hard mask film as an etching mask.

In an embodiment, the method may further include forming a lower electrode on a lower surface of the substrate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view illustrating an example of a distributed reflector laser diode according to the inventive concept;

FIG. 2 is a cross-sectional view taken along line I-I′ of FIG. 1;

FIG. 3 is a plan view illustrating an example of a distributed reflector laser diode according to the inventive concept;

FIG. 4 is a cross-sectional view of the distributed reflector laser diode of FIG. 3;

FIG. 5 is a flowchart illustrating a method for manufacturing a distributed reflector laser diode according to the inventive concept;

FIGS. 6 to 11 are cross-sectional views illustrating a manufacturing process of a distributed reflector laser diode according to the inventive concept;

FIG. 12 is a cross-sectional view illustrating an example of a distributed reflector laser diode according to the inventive concept;

FIG. 13 is a plan view illustrating an example of a distributed reflector laser diode according to the inventive concept;

FIG. 14 is a cross-sectional view taken along line I-I′ of FIG. 13;

FIG. 15 is a plan view illustrating an example of a distributed reflector laser diode in which an optical amplifier is integrated according to the inventive concept;

FIG. 16 is a cross-sectional view of the distributed reflector laser diode in which an optical amplifier is integrated of FIG. 15;

FIG. 17 is a flowchart illustrating a method for manufacturing a distributed reflector laser diode according to the inventive concept;

FIGS. 18 to 24 are cross-sectional views illustrating a manufacturing process of a distributed reflector laser diode according to the inventive concept;

FIG. 25 is a plan view illustrating an example of a distributed reflector laser diode according to the inventive concept;

FIG. 26 is a cross-sectional view taken along line I-I′ of FIG. 25;

FIG. 27 is a plan view illustrating an example of a distributed reflector laser diode in which an optical amplifier is integrated according to the inventive concept;

FIG. 28 is a cross-sectional view of the distributed reflector laser diode in which an optical amplifier is integrated of FIG. 27;

FIG. 29 is a flowchart illustrating a method for manufacturing a distributed reflector laser diode according to the inventive concept;

FIGS. 30 to 35 are cross-sectional views illustrating a manufacturing process of a distributed reflector laser diode according to the inventive concept;

FIG. 36 is a plan view illustrating an example of a distributed reflector laser diode according to the inventive concept;

FIG. 37 is a cross-sectional view taken along line I-I′ of FIG. 36;

FIG. 38 is a plan view illustrating an example of a distributed reflector laser diode according to the inventive concept;

FIG. 39 is a cross-sectional view of the distributed reflector laser diode of FIG. 38;

FIG. 40 is a flowchart illustrating a method for manufacturing a distributed reflector laser diode according to the inventive concept;

FIGS. 41 to 47 are cross-sectional views illustrating a manufacturing process of a distributed reflector laser diode according to the inventive concept;

FIGS. 48 and 49 are cross-sectional views illustrating an example of the current blocking layer on an outer periphery of the active waveguide layer of FIG. 46;

FIG. 50 is a cross-sectional view illustrating the ridge waveguide of the upper clad layer of FIG. 37;

FIG. 51 is a plan view illustrating an example of a distributed reflector laser diode according to the inventive concept;

FIG. 52 is a cross-sectional view taken along line I-I′ of FIG. 51;

FIG. 53 is a plan view illustrating an example of a distributed reflector laser diode according to the inventive concept;

FIG. 54 is a cross-sectional view of the distributed reflector laser diode of FIG. 53;

FIG. 55 is a flowchart illustrating a method for manufacturing a distributed reflector laser diode according to the inventive concept;

FIGS. 56 to 61 are cross-sectional views illustrating a manufacturing process of a distributed reflector laser diode according to the inventive concept;

FIGS. 62 and 63 are cross-sectional views illustrating an example of the current blocking layer on an outer periphery of the active layer and the first hard mask film of FIG. 57; and

FIG. 64 is a cross-sectional view illustrating the ridge waveguide of the clad layer of FIG. 52.

### DETAILED DESCRIPTION

Embodiments of the inventive concept will now be described in detail with reference to the accompanying drawings. Advantages and features of embodiments of the inventive concept, and methods for achieving the advantages and features will be apparent from the embodiments described in detail below with reference to the accompanying drawings. However, the inventive concept may be embodied in different forms and should not be construed as limited to the embodiments set forth herein. Rather, these embodiments are provided so that this disclosure will be thorough and complete, and will fully convey the scope of the inventive concept to those skilled in the art, and the inventive concept is only defined by the scope of the claims. Like reference numerals refer to like elements throughout.

The terminology used herein is not for delimiting the embodiments of the inventive concept but for describing the embodiments. The terms of a singular form may include plural forms unless otherwise specified. It will be further understood that the terms “includes”, “including”, “comprises”, and/or “comprising”, when used ‘in this description, specify the presence of stated elements, operations, and/or components, but do not preclude the presence or addition of one or more other elements, operations, and/or components. Furthermore, reference numerals, which are presented in the order of description, are provided according to the embodiments and are thus not necessarily limited to the order.

The embodiments of the inventive concept will be described with reference to example cross-sectional views and/or plan views. In the drawings, the dimensions of layers and regions are exaggerated for clarity of illustration. Therefore, the forms of the example drawings may be changed due to a manufacturing technology and/or error tolerance. Therefore, the embodiments of the inventive concept may involve changes of shapes depending on a manufacturing process, without being limited to the illustrated specific forms.

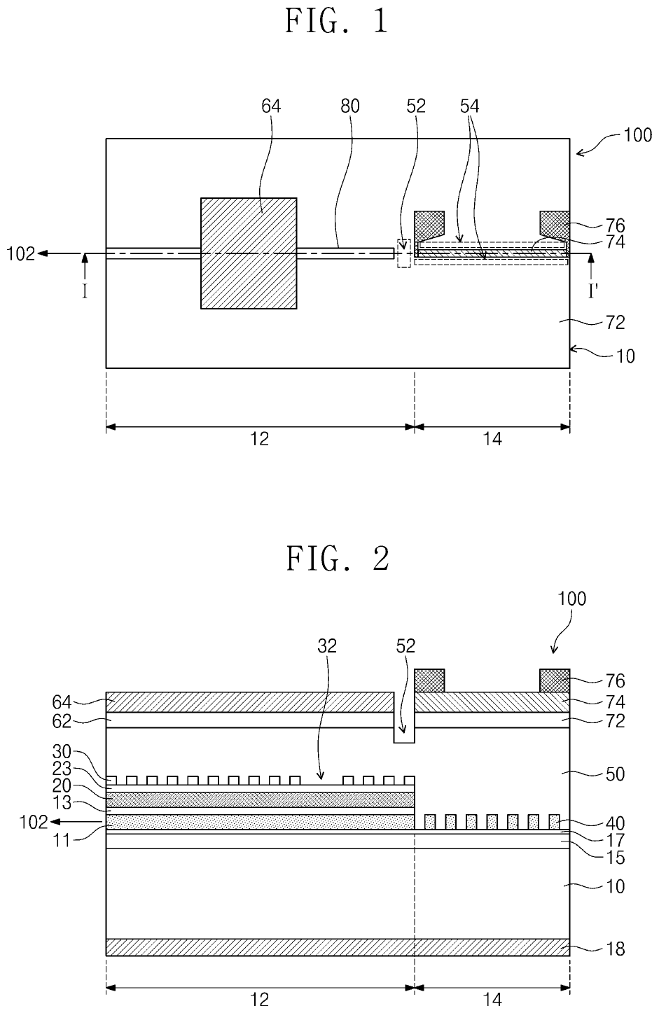

FIG. 1 illustrates an example of a distributed reflector laser diode 100 according to the inventive concept. FIG. 2 is a cross-sectional view taken along line I-I′ of FIG. 1.

Referring to FIGS. 1 and 2, the distributed reflector laser diode 100 according to the inventive concept may include a butt coupled waveguide laser diode. According to an example, the distributed reflector laser diode 100 according to the inventive concept may include a substrate 10, a lower clad layer 11, an active layer 20, a first lattice 30, a second lattice 40, an upper clad layer 50, a first upper electrode 64, and a heater layer 74.

The substrate 10 may include n-type InP. A lower electrode 18 may be provided under the substrate 10. According to an example, the substrate 10 may have a distributed feed-back (DFB) region 12 and a distributed Bragg reflection (DBR) region 14. The DFB region 12 may be provided to one side of the substrate 10. The DBR region 14 may be provided to the other side of the substrate 10 facing the DFB region 12.

A waveguide layer 15 may be provided on the substrate 10. The waveguide layer 15 may include undoped or intrinsic InP. A separation layer 17 may be provided on the waveguide layer 15. The separation layer 17 may include N-type doped InP.

The lower clad layer 11 may be provided on the separation layer 17 of the DFB region 12. The lower clad layer 11 may be a lower waveguide layer or slab waveguide layer. For example, the lower clad layer 11 may include InGaAsP. The lower clad layer 11 may have a thickness of about 20 nm to about 100 nm.

A lower spacer layer 13 may be provided on the lower clad layer 11. The lower spacer layer 13 may be thinner than the lower clad layer 11. The lower spacer layer 13 may include N-type doped InP.

The active layer 20 may be provided on the lower spacer layer 13. The active layer 20 may obtain a gain of laser light 102. For example, the active layer 20 may include a multi quantum well (MQW) active layer.

An upper spacer layer 23 may be provided on the active layer 20. The upper spacer layer 23 may include P-type doped InP.

The first lattice 30 may be provided on the upper spacer layer 23. The first lattice 30 may include InGaAsP. The first lattice 30 may have a thickness of about 20 nm to about 100 nm. The first lattice 30 may be a λ/4-shifted DFB lattice. According to an example, the first lattice 30 may have a λ/4 phase shifter 32. The λ/4 phase shifter 32 may increase single-mode oscillation of the laser light 102. The λ/4 phase shifter 32 may tune or adjust a peak wavelength of the laser light 102. The λ/4 phase shifter 32 may be provided at a position corresponding to ½ to ¼ of a length of the DFB region 12.

The second lattice 40 may be provided on the substrate 10 of the DBR region 14. The second lattice 40 may be thicker than the first lattice 30. The second lattice 40 may be deeper than the first lattice 30. The second lattice 40 may have a lower height than the active layer 20, the lower spacer layer 13, the upper spacer layer 23, and the first lattice 30. The first lattice 30 and the second lattice 40 may be single integrated on the substrate 10. The second lattice 40 may be formed in lower clad layer 11. The second lattice 40 may increase reflection efficiency of the laser light 102. The second lattice 40 may have the same material as that of the first lattice 30. For example, the second lattice 40 may include InGaAsP. The second lattice 40 may have a thickness of about 3 μm. The second lattice 40 may remove and/or replace a reflective layer on a sidewall of the substrate 10 of the DBR region 14, thus reducing a length or linewidth of the laser diode 100.

The upper clad layer 50 may be provided on the first lattice 30 and the second lattice 40. The upper clad layer 50 may include low concentration p-type InP. The upper clad layer 50 may have a first trench 52 and a second trench 54. The first trench 52 of the upper clad layer 50 may be provided between the DFB region 12 and the DBR region 14. The second trench 54 may be formed along an outer periphery of the heater layer 74 on the upper clad layer 50. For example, the first trench 52 and the second trench 54 each may have a depth of about 0.5 μm. According to an example, the upper clad layer 50 may have a mesa structure or ridge waveguide structure within the DFB region 12. The upper clad layer 50 in the DFB region 12 may be expressed as an optical waveguide 80. The upper clad layer 50 outside the optical waveguide 80 may have a depth of about 4 μm to about 5 μm.

An ohmic contact layer 62 may be provided on the upper clad layer 50 of the DFB region 12. The ohmic contact layer 62 may be provided on the optical waveguide 80 of the upper clad layer 50. The ohmic contact layer 62 may include high concentration p-type InGaAs.

The first upper electrode 64 may be provided on the ohmic contact layer 62. The first upper electrode 64 may include metal such as titanium (Ti), platinum (Pt), gold (Au), silver (Ag), or copper (Cu). The first upper electrode 64 may obtain a gain of the laser light 102 by providing an electric field in the optical waveguide 80 using an external bias voltage.

An insulating layer 72 may be provided on the upper clad layer 50 of the DBR region 14. The insulating layer 72 may be provided on an upper surface of the upper clad layer 50 on an outer periphery of the heater layer 74.

The heater layer 74 may be provided on the insulating layer 72 of the DBR region 14. The heater layer 74 may be provided in the second trench 54. The second trench 54 may have a depth of about 10 μm. The heater layer 74 may have a reverse mesa structure. The heater layer 74 may include chrome, nickel, platinum, gold, or their alloys. The heater layer 74 may tune an oscillation wavelength of the laser light 102 in the DBR region 14 by heating the upper clad layer 50 and the second lattice 40 using a heating voltage. The second lattice 40 may reflect the laser light 102 to the DFB region 12. The second lattice 40 may remove a reflective layer on a sidewall of the substrate 10 of the DBR region 14, thus reducing a length or linewidth of the laser diode 100.

Heater pads 76 may be connected to terminals on both sides of the heater layer 74. The heater pads 76 may provide a heating voltage to the heater layer 74.

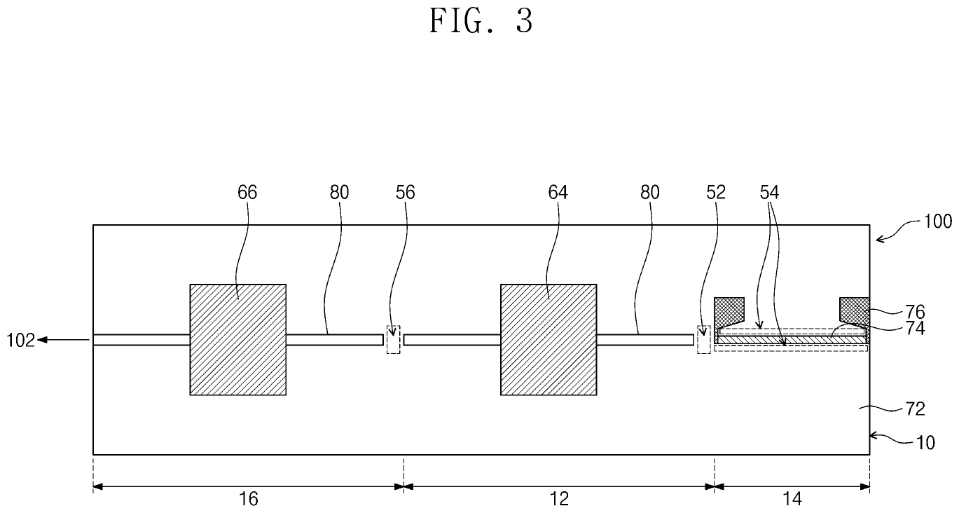

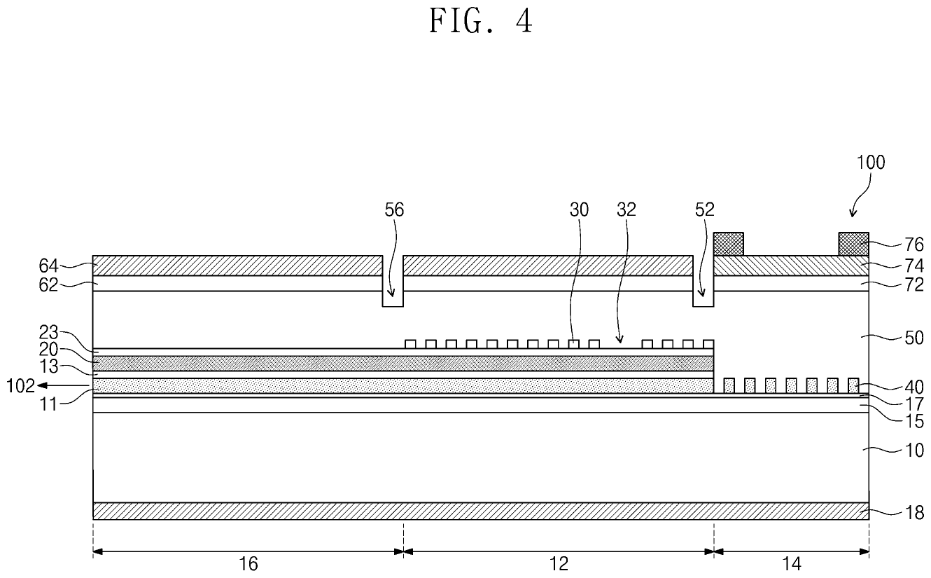

FIG. 3 illustrates an example of the distributed reflector laser diode 100 according to the inventive concept. FIG. 4 is a cross-sectional view of the distributed reflector laser diode 100 of FIG. 3.

Referring to FIGS. 3 and 4, the substrate 10 of the distributed reflector laser diode 100 according to the inventive concept may further include a semiconductor optical amplifier region 16.

The semiconductor optical amplifier region 16 may be provided on one side of the DFB region 12 facing the DBR region 14. The semiconductor optical amplifier region 16 may be a region amplifying power of the laser light 102.

The lower clad layer 11, the lower spacer layer 13, the active layer 20, and the upper spacer layer 23 may extend from the DFB region 12 to the semiconductor optical amplifier region 16.

The upper clad layer 50 may have a third trench 56. The third trench 56 may be provided between the DFB region 12 and the semiconductor optical amplifier region 16. A depth of the third trench 56 may be equal to or larger than a depth of the first trench 52. The third trench 56 may have a depth of about 0.5 μm.

The ohmic contact layer 62 and a second upper electrode 66 may be provided on the upper clad layer 50 of the semiconductor optical amplifier region 16. The second upper electrode 66 may be provided on the ohmic contact layer 62. When a bias voltage is provided to the second upper electrode 66, an electric field may be generated between the second upper electrode 66 and the lower electrode 18. The active layer 20 may amplify the power of the laser light 102 in proportion to the electric field.

The substrate 10, the lower clad layer 11, the lower spacer layer 13, the active layer 20, the upper spacer layer 23, the first lattice 30, the second lattice 40, the upper clad layer 50, the first upper electrode 64, the insulating layer 72, the heater layer 74, and the heater pads 76 of the DFB region 12 and DBR region 14 may be configured in the same manner as illustrated in FIGS. 1 and 2.

A method for manufacturing the distributed reflector laser diode 100 of the inventive concept configured as described above is described below.

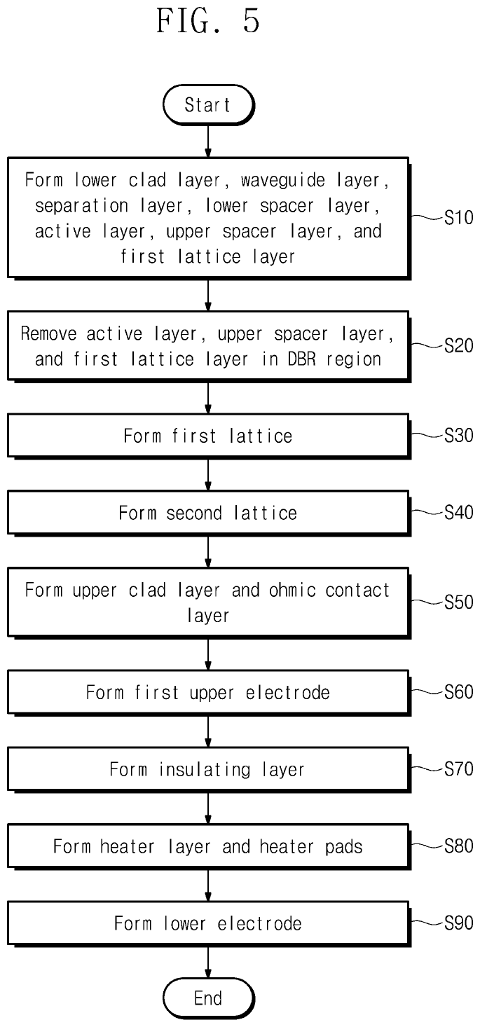

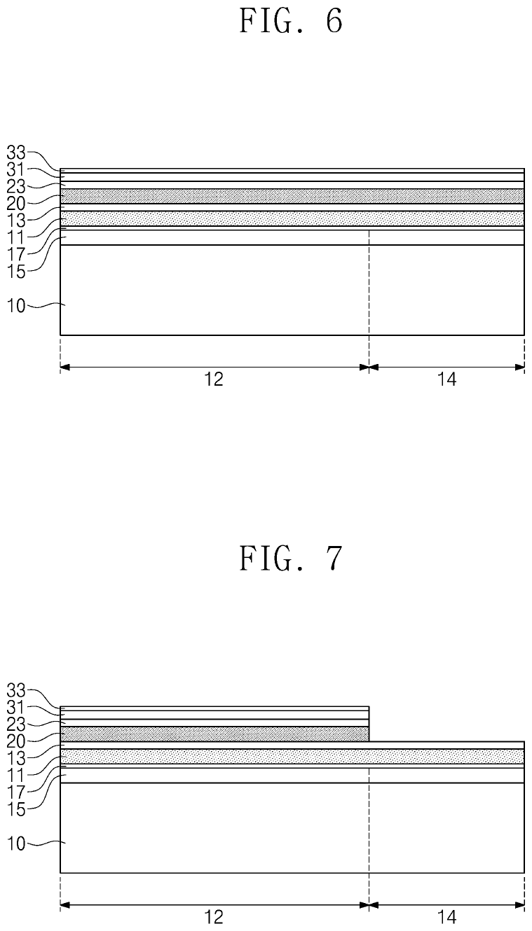

FIG. 5 illustrates a method for manufacturing the distributed reflector laser diode 100 according to the inventive concept. FIGS. 6 to 11 are cross-sectional views illustrating a manufacturing process of the distributed reflector laser diode 100 according to the inventive concept.

Referring to FIGS. 5 and 6, the waveguide layer 15, the separation layer 17, the lower clad layer 11, the lower spacer layer 13, the active layer 20, the upper spacer layer 23, a first lattice layer 31, and a first cap layer 33 are formed on the substrate 10 (S10). The waveguide layer 15 may include undoped InP. The separation layer 17 may be formed on the waveguide layer 15. The separation layer 17 may include N-type doped InP. The lower clad layer 11 may be formed on the separation layer 17. The lower clad layer 11 may include InGaAsP. The lower spacer layer 13 may be formed on the lower clad layer 11. The lower spacer layer 13 may include n-type InP. The active layer 20 may be formed on the substrate 10. The active layer 20 may include a multi quantum well (MQW) active layer. The upper spacer layer 23 may be provided on the active layer 20. The upper spacer layer 23 may include p-type InP. The first lattice layer 31 may be formed on the upper spacer layer 23. The first lattice layer 31 may include InGaAsP. The first lattice layer 31 may have a thickness of about 300 nm. The upper spacer layer 23 may be formed on the first lattice layer 31. The upper spacer layer 23 may include p-type InP. The first cap layer 33 may be formed on the upper spacer layer 23. The first cap layer 33 may include p-type InP. The first cap layer 33 may have a thickness of about 20 nm.

Referring to FIGS. 5 and 7, the active layer 20, the upper spacer layer 23, the first lattice layer 31, and the first cap layer 33 of the DBR region 14 are removed (S20). Although not illustrated, the active layer 20, the upper spacer layer 23, the first lattice layer 31, and the first cap layer 33 may be removed through a photolithography process and etching process.

Referring to FIGS. 5, 8, and 9, the first lattice 30 is formed by partially removing the first lattice layer 31 using a photolithography process and etching process (S30).

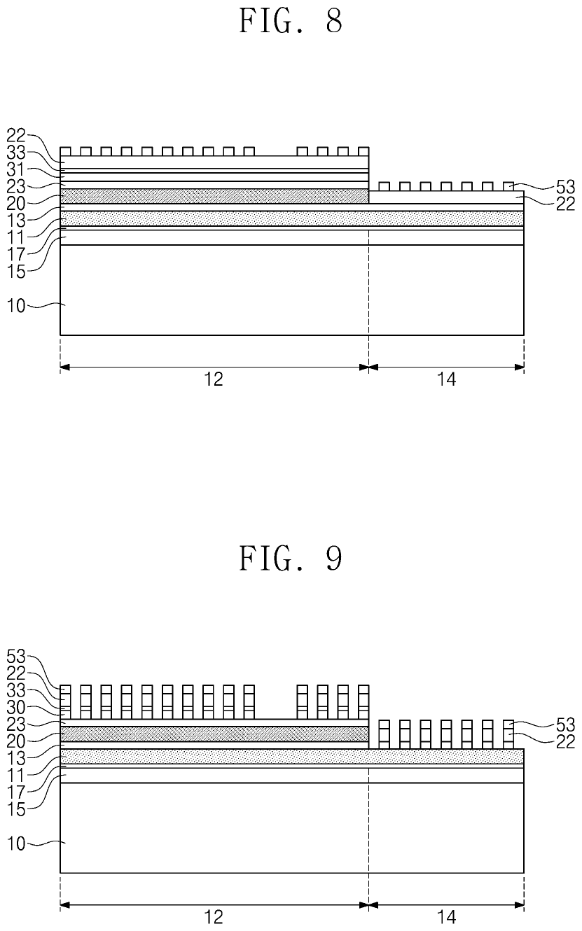

Referring to FIGS. 8 and 9, the first lattice 30 may be formed in the DFB region 12 through an etching process in which a first hard mask film 22 and a first photoresist pattern 53 are used as an etching mask. The first photoresist pattern 53 may be formed through an e-beam lithography process. The first photoresist pattern 53 may be formed through a photolithography process, but an embodiment of the inventive concept is not limited thereto. The first hard mask film 22 and the first photoresist pattern 53 may be formed on the lower spacer layer 13 of the DBR region 14.

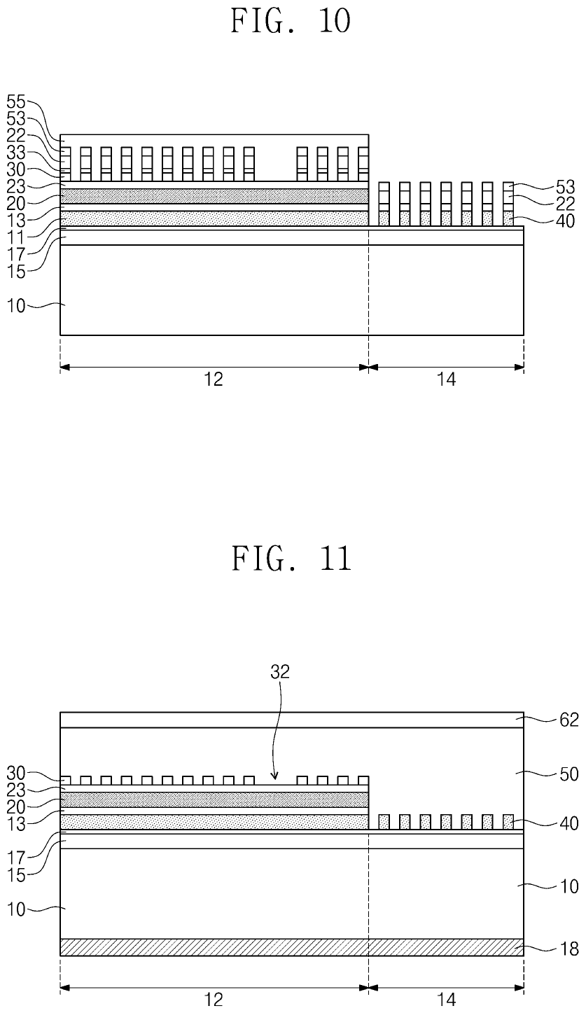

Referring to FIGS. 5 and 10, the second lattice 40 is formed in the DBR region 14 (S40). A second hard mask film 55 may be formed on the first photoresist pattern 53 and the first hard mask film 22 of the DFB region 12. The second hard mask film 55 may include silicon nitride (SiN). The second lattice 40 may be formed through an etching process in which the second hard mask film 55 of the DFB region 12 and the first photoresist pattern 53 and the first hard mask film 22 of the DBR region 14 are used as an etching mask.

Thereafter, the first hard mask film 22, the first cap layer 33, the first photoresist pattern 53, and the second hard mask film 55 may be removed.

Referring to FIGS. 5 and 11, the upper clad layer 50 and the ohmic contact layer 62 are formed on the first lattice 30 and the second lattice 40 (S50).

Next, the first upper electrode 64 is formed on the ohmic contact layer 62 of the DFB region 12 (S60).

Referring to FIGS. 2 and 5, the upper clad layer 50 is exposed by removing the ohmic contact layer 62 of the DBR region 14, and the insulating layer 72 is formed on the upper clad layer 50 of the DBR region 14 (S70). The insulating layer 72 may include a dielectric of silicon nitride or silicon oxide formed using a chemical vapor deposition method.

Next, the heater layer 74 and the heater pads 76 are formed on the insulating layer 72 (S80).

Furthermore, the lower electrode 18 is formed on a lower surface of the substrate 10 (S90).

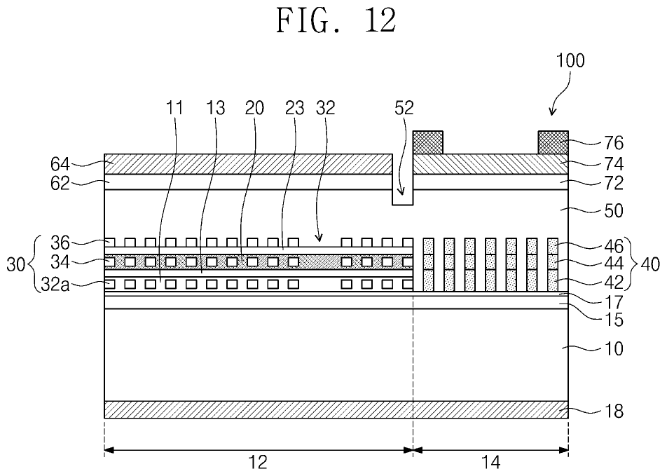

FIG. 12 illustrates an example of the distributed reflector laser diode 100 according to the inventive concept.

Referring to FIG. 12, the first lattice 30 of the distributed reflector laser diode 100 according to the inventive concept may include a first lower lattice 32a, a first intermediate lattice 34, and a first upper lattice 36. The first lower lattice 32a, the first intermediate lattice 34, and the first upper lattice 36 may be provided in the DFB region 12. The first lower lattice 32a, the first intermediate lattice 34, and the first upper lattice 36 may be discontinuously arranged in a direction perpendicular to the substrate 10. The first lower lattice 32a may be provided in the lower clad layer 11. The first intermediate lattice 34 may be provided in the active layer 20. The first upper lattice 36 may be provided between the upper spacer layer 23 and the upper clad layer 50.

The second lattice 40 may be provided in the DBR region 14. The second lattice 40 may include a second lower lattice 42, a second intermediate lattice 44, and a second upper lattice 46. The second lower lattice 42, the second intermediate lattice 44, and the second upper lattice 46 of the second lattice 40 may be continuously arranged in a direction perpendicular to the substrate 10. The second lower lattice 42 may be provided adjacent to the first lower lattice 32a. The second intermediate lattice 44 may be provided on the second lower lattice 42. The second intermediate lattice 44 may be provided adjacent to the first intermediate lattice 34. The second upper lattice 46 may be provided on the second intermediate lattice 44. The second upper lattice 46 may be provided adjacent to the first upper lattice 36.

The substrate 10, the waveguide layer 15, the lower electrode 18, the lower spacer layer 13, the upper spacer layer 23, the upper clad layer 50, the ohmic contact layer 62, the first upper electrode 64, the insulating layer 72, the heater layer 74, and the heater pads 76 may be configured in the same manner as illustrated in FIG. 2.

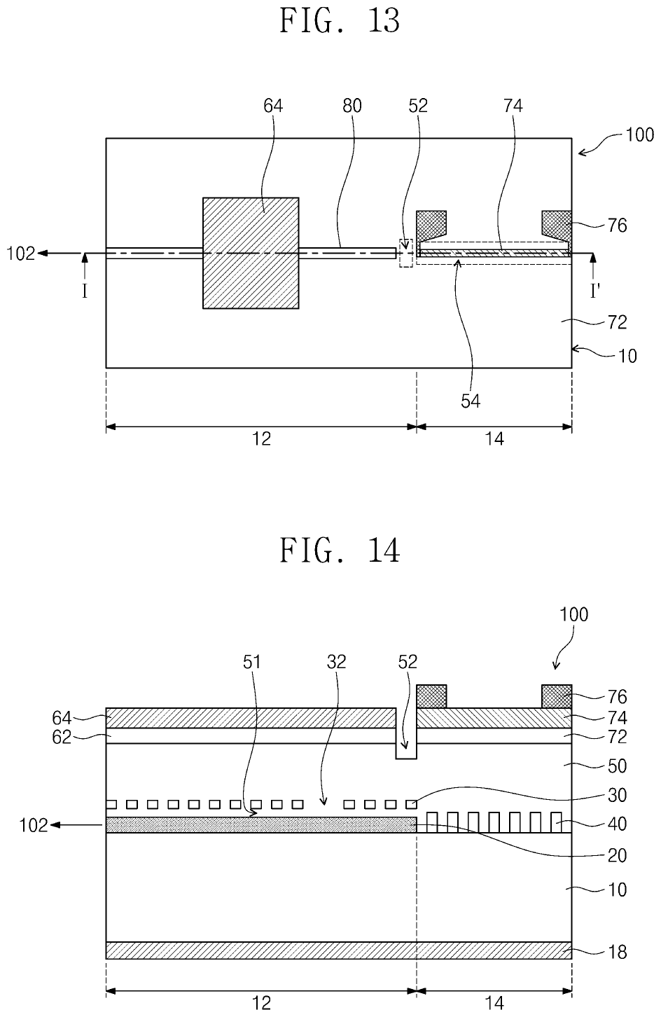

FIG. 13 illustrates an example of the distributed reflector laser diode 100 according to the inventive concept. FIG. 14 is a cross-sectional view taken along line I-I′ of FIG. 13.

Referring to FIGS. 13 and 14, the distributed reflector laser diode 100 according to the inventive concept may include a butt waveguide joint laser diode. According to an example, the distributed reflector laser diode 100 according to the inventive concept may include a substrate 10, an active layer 20, a first lattice 30, a second lattice 40, a clad layer 50, a first upper electrode 64, and a heater layer 74.

The substrate 10 may include n-type InP. A lower electrode 18 may be provided under the substrate 10. According to an example, the substrate 10 may have a distributed feed-back (DFB) region 12 and a distributed Bragg reflection (DBR) region 14.

The active layer 20 may be optionally provided on the substrate 10 of the DFB region 12. The active layer 20 may obtain a gain of laser light 102. For example, the active layer 20 may include a multi quantum well (MQW) active layer.

The first lattice 30 may be provided on the active layer 20 of the DFB region 12. The first lattice 30 may include 1.0 to 1.3 μm InGaAsP. The first lattice 30 may be a λ/4-shifted DFB lattice. According to an example, the first lattice 30 may have a λ/4 phase shifter 32. The λ/4 phase shifter 32 may increase single-mode oscillation of the laser light 102. The λ/4 phase shifter 32 may tune or adjust a peak wavelength of the laser light 102. The λ/4 phase shifter 32 may be provided at a position corresponding to ½ to ¼ of a length of the DFB region 12. A spacer layer 51 may be provided between the first lattice 30 and the active layer 20. The spacer layer 51 may include p-type InP. The spacer layer 51 may include n-type InP. The spacer layer 51 may include p-type InP, but an embodiment of the inventive concept is not limited thereto.

The second lattice 40 may be provided on the substrate 10 of the DBR region 14. The second lattice 40 may be thicker than the active layer 20. The second lattice 40 may be thicker than the first lattice 30. The second lattice 40 may be deeper than the first lattice 30. The second lattice 40 may have a lower height than the active layer 20, the spacer layer 51, and the first lattice 30.

The second lattice 40 may increase reflection efficiency of the laser light 102. The second lattice 40 may have the same material as that of the first lattice 30. For example, the second lattice 40 may include 1.0 to 1.3 μm InGaAsP. The second lattice 40 may remove a reflective layer on a sidewall of the substrate 10 of the DBR region 14, thus reducing a length or linewidth of the laser diode 100.

The clad layer 50 may be provided on the first lattice 30 and the second lattice 40. The clad layer 50 may include p-type InP. The clad layer 50 may have a first electrode isolation region 52 and a first trench 54. The first electrode isolation region 52 of the clad layer 50 may be provided between the DFB region 12 and the DBR region 14. The first electrode isolation region 52 of the clad layer 50 may provide a function of isolating an electrode between the DFB region 12 and the DBR region 14. The first trench 54 may be formed along an outer periphery of the heater layer 74 on the clad layer 50. According to an example, the clad layer 50 may have a mesa-type planar buried heterostructure (PBH) structure or ridge waveguide structure within the DFB region 12. The clad layer 50 in the DFB region 12 may be expressed as an optical waveguide 80. The clad layer 50 outside the optical waveguide 80 may have a depth of about 4 μm to about 5 μm.

An ohmic contact layer 62 may be provided on the clad layer 50 of the DFB region 12. The ohmic contact layer 62 may be provided on the optical waveguide 80 of the clad layer 50. The ohmic contact layer 62 may include high concentration p-type InGaAs.

The first upper electrode 64 may be provided on the ohmic contact layer 62. The first upper electrode 64 may include metal such as titanium (Ti), platinum (Pt), or gold (Au). The first upper electrode 64 may obtain a gain of the laser light 102 by introducing current into the optical waveguide 80 using an external bias voltage.

An insulating layer 72 may be provided on the clad layer 50 of the DBR region 14. The insulating layer 72 may be provided on an upper surface of the clad layer 50 on an outer periphery of the heater layer 74.

The heater layer 74 may be provided on the insulating layer 72 of the DBR region 14. The heater layer 74 may be provided in the first trench 54. The first trench 54 may have a depth of about 10 μm. The heater layer 74 may have a reverse mesa structure.

The heater layer 74 may include chrome and nickel alloys. The heater layer 74 may tune an oscillation wavelength of the laser light 102 in the DBR region 14 by heating the clad layer 50 and the second lattice 40 using a heating voltage. The second lattice 40 may reflect the laser light 102 to the DFB region 12. The second lattice 40 may remove a reflective layer on a sidewall of the substrate 10 of the DBR region 14, thus reducing a length or linewidth of the laser diode 100.

Heater pads 76 may be connected to terminals on both sides of the heater layer 74. The heater pads 76 may provide a heating voltage to the heater layer 74.

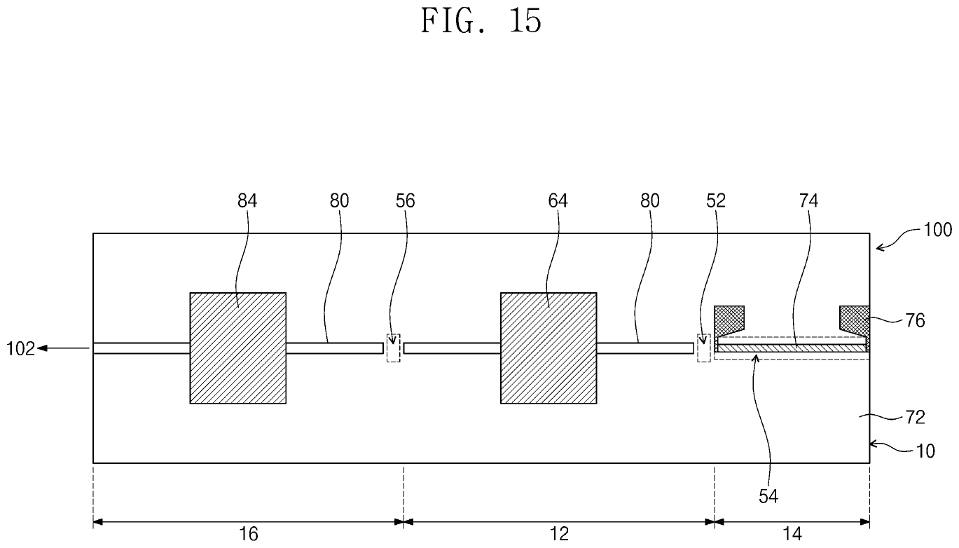

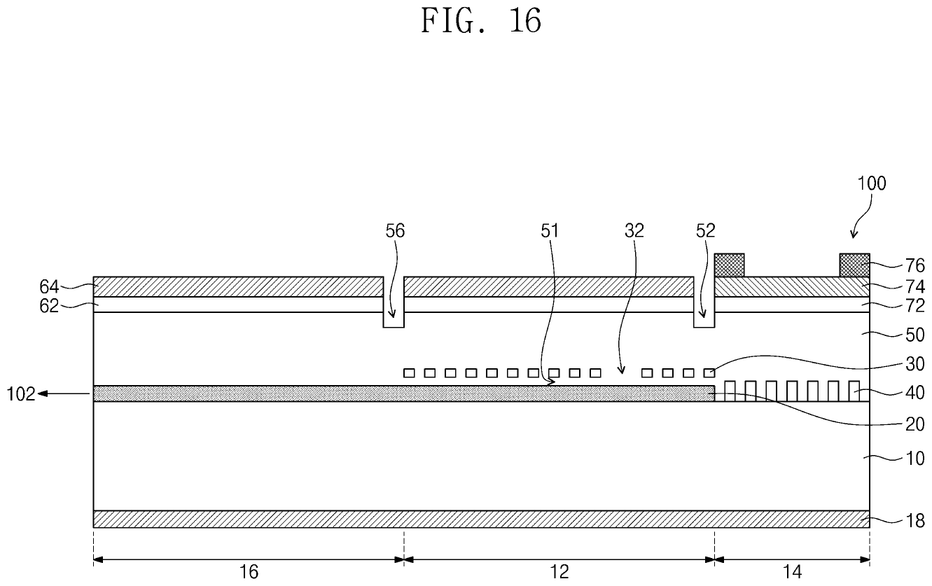

FIG. 15 illustrates an example of the distributed reflector laser diode 100 according to the inventive concept. FIG. 16 is a cross-sectional view of the distributed reflector laser diode 100 of FIG. 15.

Referring to FIGS. 15 and 16, the substrate 10 of the distributed reflector laser diode 100 according to the inventive concept may further include a semiconductor optical amplifier region 16.

The semiconductor optical amplifier region 16 may be provided on one side of the DFB region 12 facing the DBR region 14. The semiconductor optical amplifier region 16 may be a region amplifying power of the laser light 102.

The active layer 20 may extend from the DFB region 12 to the semiconductor optical amplifier region 16.

The clad layer 50 may have a second electrode isolation part 56. The second electrode isolation part 56 may isolate electrodes of the DFB region 12 and the semiconductor optical amplifier region 16 on two sides of the clad layer 50. The second trench 56 may have the same depth as the first trench 52. The second trench 56 may have a depth of about 0.5 μm.

The ohmic contact layer 62 and a second upper electrode 84 may be provided on the clad layer 50 of the semiconductor optical amplifier region 16. The second upper electrode 84 may be provided on the ohmic contact layer 62. When a bias voltage is provided to the second upper electrode 84, an electric field may be generated between the second upper electrode 84 and the lower electrode 18. The active layer 20 may amplify the power of the laser light 102 in proportion to the electric field.

The substrate 10, the active layer 20, the first lattice 30, the second lattice 40, the clad layer 50, the first upper electrode 64, and the heater layer 74 of the DFB region 12 and DBR region 14 may be configured in the same manner as illustrated in FIGS. 1 and 2.

A method for manufacturing the distributed reflector laser diode 100 of the inventive concept configured as described above is described below.

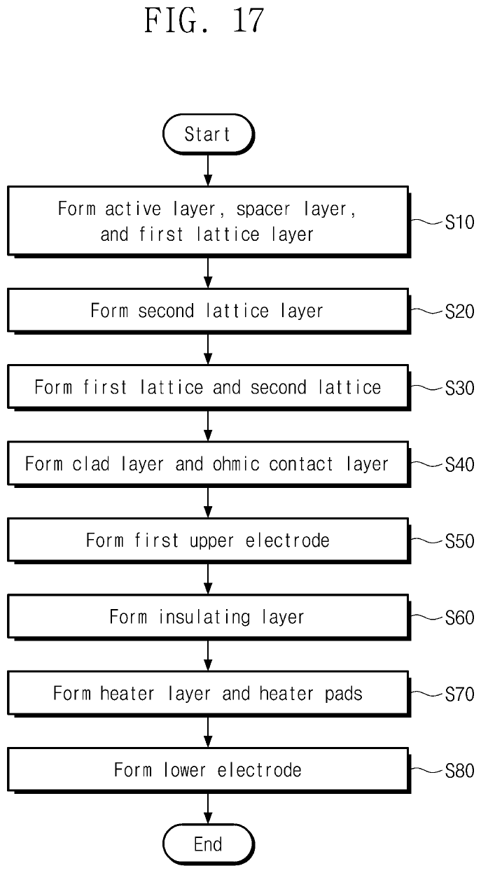

FIG. 17 illustrates a method for manufacturing the distributed reflector laser diode 100 according to the inventive concept. FIGS. 18 to 24 are cross-sectional views illustrating a manufacturing process of the distributed reflector laser diode 100 according to the inventive concept.

Referring to FIGS. 17 and 18, the active layer 20, the spacer layer 51, the first lattice layer 31, and the first cap layer 33 are formed on the substrate 10 (S10). The active layer 20 may be formed on the substrate 10. The active layer 20 may include a multi quantum well (MQW) active layer. The spacer layer 51 may be formed on the active layer 20. The spacer layer 51 may include p-type InP. The spacer layer 51 may include p-type InP, but an embodiment of the inventive concept is not limited thereto. The first lattice layer 31 may be formed on the spacer layer 51. The first lattice layer 31 may include InGaAsP of 1.0 to 1.3 μm composition. The first lattice layer 31 may have a thickness of about 20 to 40 nm. The first cap layer 33 may be formed on the first lattice layer 31. The first cap layer 33 may include p-type InP. The first cap layer 33 may have a thickness of about 20 nm. A first hard mask 35 may be formed on the first cap layer 33. The first hard mask 35 may include silicon nitride.

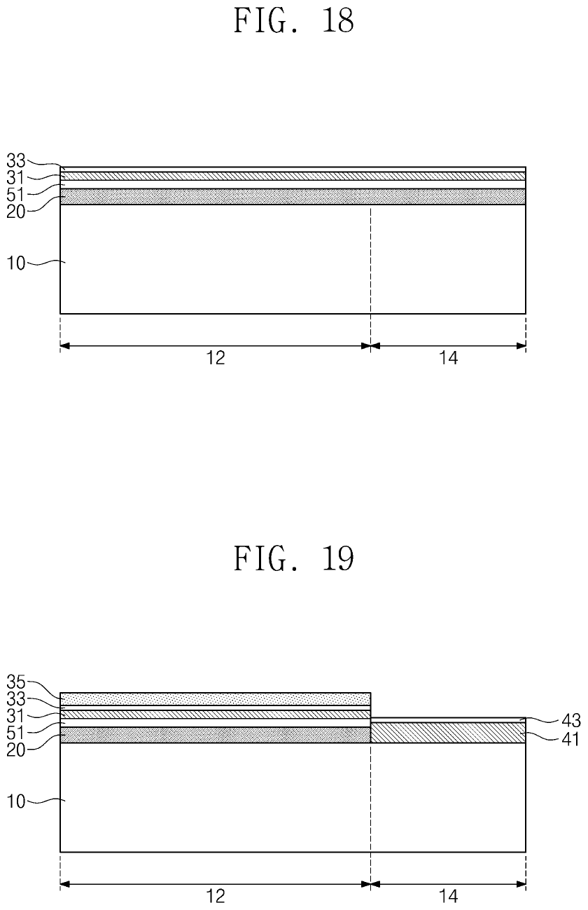

Referring to FIGS. 17 and 19, the substrate 10 is exposed by partially removing the active layer 20, the spacer layer 51, the first lattice layer 31, and the first cap layer 33 of the DBR region 14, and a second lattice layer 41 and a second cap layer 43 are regrown (S20). The second lattice layer 41 may be formed through butt regrowth. The second lattice layer 41 may have the same material as that of the first lattice layer 31. The second lattice 41 may include InGaAsP of 1.2 to 1.3 μm composition. The second cap layer 43 may be formed on the second lattice layer 41. The second cap layer 43 may have the same material as that of the first cap layer 33. The second cap layer 43 may include p-type InP. A second hard mask 45 may be formed on the second cap layer 43. The second hard mask 45 may include silicon nitride (SiN). The first hard mask 35 and the second hard mask 45 may be simultaneously formed on the first cap layer 33 and the second cap layer 43, but an embodiment of the inventive concept is not limited thereto.

Referring to FIGS. 17 and 20 to 23, the first lattice 30 and the second lattice 40 are formed by partially removing the first lattice layer 31, the second lattice layer 41, the second cap layer 43, the first hard mask 33, and the second hard mask 45 using an e-beam lithography process (S30).

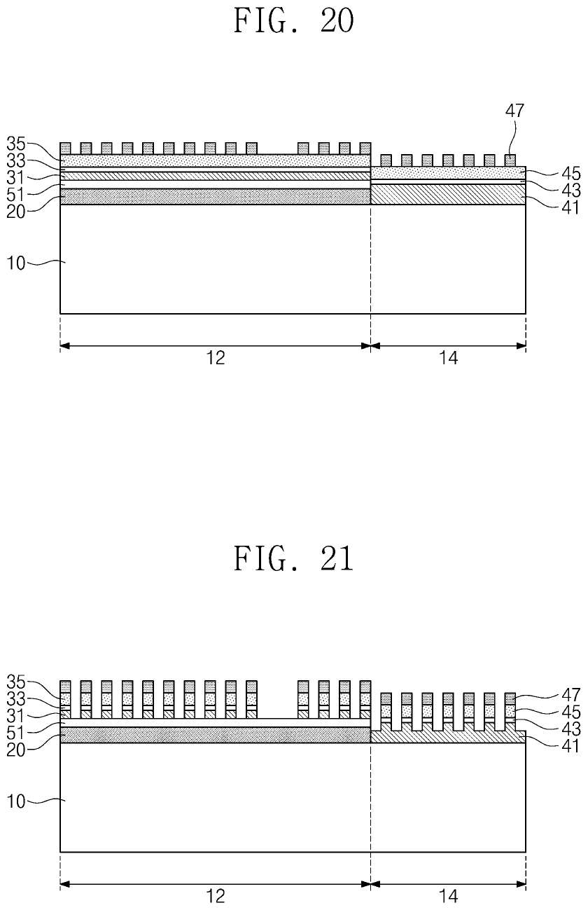

Referring to FIGS. 20 and 21, the first lattice 30 may be formed through an etching process in which the first hard mask 35 and a first lattice pattern 47 are used as an etching mask. The first lattice pattern 47 may be formed through an e-beam lithography process. The second lattice layer 41, the second cap layer 43, and the second hard mask 45 may be partially removed during an etching process of the first lattice 30. Thereafter, a third hard mask 48 may be formed on the first lattice pattern 47 to protect the first lattice 30 formed in the DFB region 12. The first lattice 30 may have a λ/4 phase shifter 32.

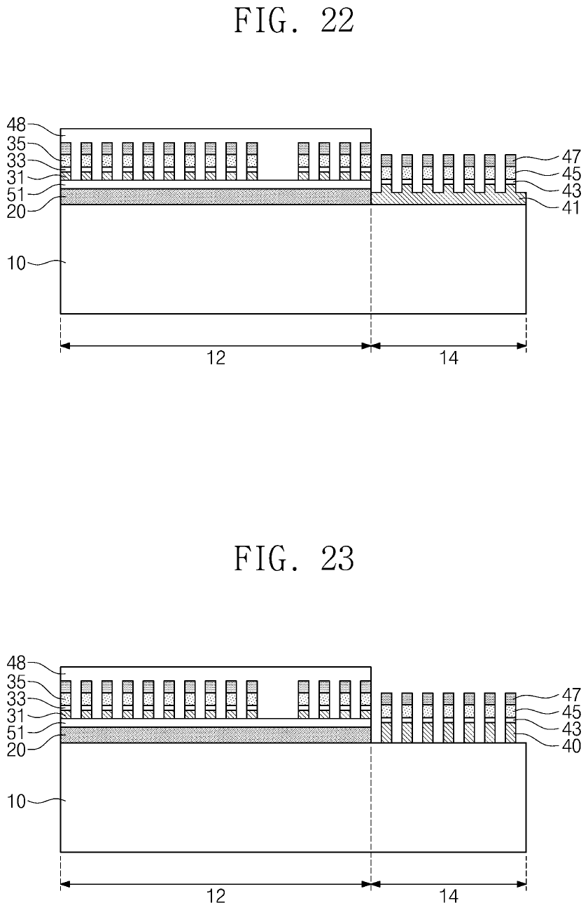

Referring to FIGS. 22 and 23, an etching process in which the third hard mask 48 is used as a mask only in the DFB region 12 may be performed to protect the first lattice 30 of the DFB region 12. The second lattice 40 is formed by partially removing the waveguide layer 21 of the DBR region 14 using an etching process in which the third hard mask 48 is used. The second lattice 40 may be deeper than the first lattice 30.

In the DBR region 14, the second lattice 40 may have a depth or thickness of about 250 nm. Thereafter, the first lattice pattern 47, the third hard mask 48, the first hard mask 35, and the second hard mask 45 may be removed.

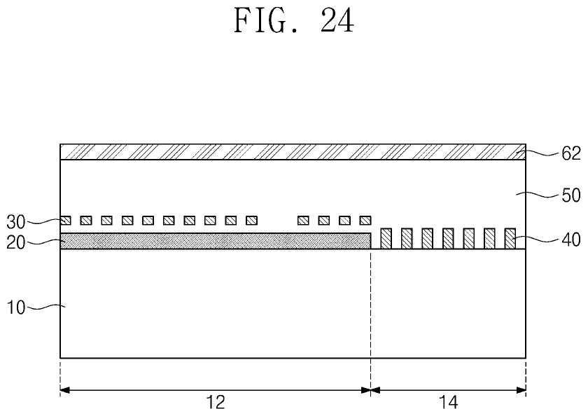

Referring to FIGS. 17 and 24, the clad layer 50 and the ohmic contact layer 62 are formed on the first lattice 30 and the second lattice 40 (S40).

Referring to FIGS. 14 and 17, the first upper electrode 64 is formed on the ohmic contact layer 62 of the DFB region 12 (S50).

Next, the clad layer 50 is exposed by removing the ohmic contact layer 62 of the DBR region 14, and the insulating layer 72 is formed on the clad layer 50 of the DBR region 14 (S60). The insulating layer 72 may include a dielectric of silicon oxide or silicon nitride.

Next, the heater layer 74 and the heater pads 76 are formed on the insulating layer 72 of the DBR region 14 (S70).

Furthermore, the lower electrode 18 is formed on a lower surface of the substrate 10 (S80).

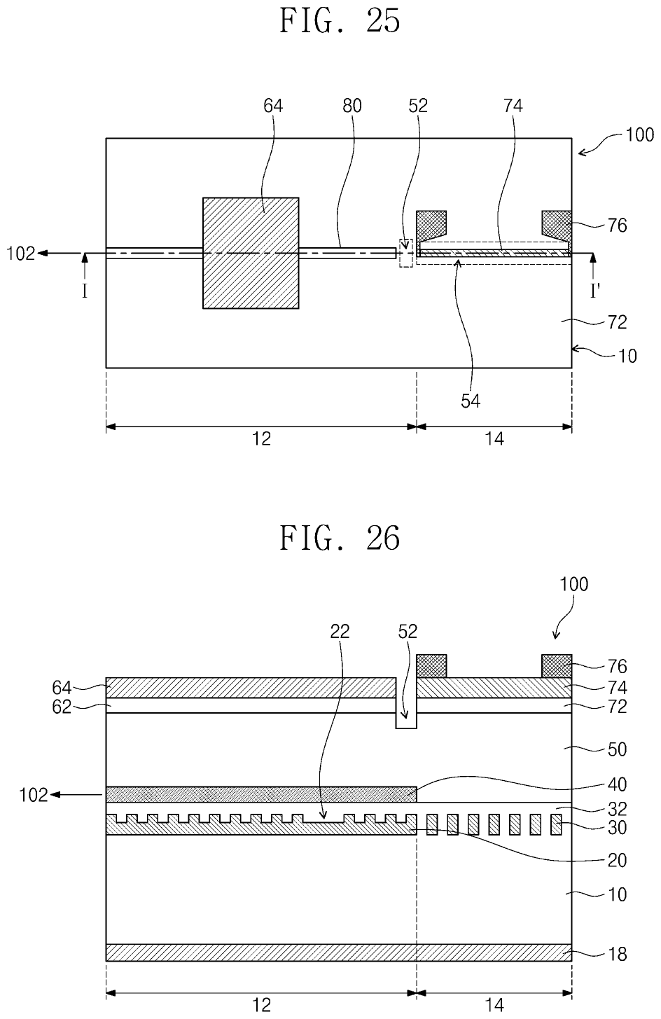

FIG. 25 illustrates an example of the distributed reflector laser diode 100 according to the inventive concept. FIG. 26 is a cross-sectional view taken along line I-I′ of FIG. 25.

Referring to FIGS. 25 and 26, the distributed reflector laser diode 100 according to the inventive concept may include a twin-waveguide laser diode. According to an example, the distributed reflector laser diode 100 according to the inventive concept may include a substrate 10, a first lattice 20, a second lattice 30, an active layer 40, a clad layer 50, a first upper electrode 64, and a heater layer 74.

The substrate 10 may include n-type InP. A lower electrode 18 may be provided under the substrate 10. According to an example, the substrate 10 may have a distributed feed-back (DFB) region 12 and a distributed Bragg reflection (DBR) region 14.

The first lattice 20 may be provided on the substrate 10 of the DFB region 12. The first lattice 20 may have a comb shape when viewed in a vertical direction. The first lattice 20 may include 1.0 to 1.3 μm InGaAsP. The first lattice 20 may be a λ/4-shifted DFB lattice. According to an example, the first lattice 20 may have a λ/4 phase shifter 22. The λ/4 phase shifter 22 may increase single-mode oscillation of the laser light 102. The λ/4 phase shifter 22 may tune or adjust a peak wavelength of the laser light 102. The λ/4 phase shifter 22 may be provided at a position corresponding to ½ to ¼ of a length of the DFB region 12.

The second lattice 30 may be provided on the substrate 10 of the DBR region 14. The second lattice 30 may have the same thickness as that of the first lattice 20. The second lattice 30 may be deeper than the first lattice 20.

The second lattice 30 may increase reflection efficiency of the laser light 102. The second lattice 30 may have the same material as that of the first lattice 20. For example, the second lattice 30 may include 1.0 to 1.3 μm InGaAsP. The second lattice 30 may remove a reflective layer on a sidewall of the substrate 10 of the DBR region 14, thus reducing a length or linewidth of the laser diode 100.

A spacer layer 32 may be provided on the the first lattice 20 and the second lattice 30. The spacer layer 32 may include p-type InP. The spacer layer 32 may include n-type InP, but an embodiment of the inventive concept is not limited thereto.

The active layer 40 may be optionally provided on the substrate 10 of the DFB region 12. The active layer 40 may obtain a gain of laser light 102. For example, the active layer 40 may include a multi quantum well (MQW) active layer.

The clad layer 50 may be provided on the active layer 40 and the spacer layer 32. The clad layer 50 may include low concentration p-type InP. The clad layer 50 may have a first electrode isolation region 52 and a first trench 54. The first electrode isolation region 52 of the clad layer 50 may provide a function of isolating an electrode between the DFB region 12 and the DBR region 14. The first trench 54 may be formed along an outer periphery of the heater layer 74 on the clad layer 50. According to an example, the clad layer 50 may have a mesa-type planar buried heterostructure (PBH) structure or ridge waveguide structure within the DFB region 12. The clad layer 50 in the DFB region 12 may be expressed as an optical waveguide 80. The clad layer 50 outside the optical waveguide 80 may have a depth of about 4 μm to about 5 μm.

An ohmic contact layer 62 may be provided on the clad layer 50 of the DFB region 12. The ohmic contact layer 62 may be provided on the optical waveguide 80 of the clad layer 50. The ohmic contact layer 62 may include high concentration p-type InGaAs.

The first upper electrode 64 may be provided on the ohmic contact layer 62. The first upper electrode 64 may include metal such as gold (Au), silver (Ag), copper (Cu), aluminum (Al), or tungsten (W). The first upper electrode 64 may obtain a gain of the laser light 102 by introducing current into the optical waveguide 80 using an external bias voltage.

An insulating layer 72 may be provided on the clad layer 50 of the DBR region 14. The insulating layer 72 may be provided on an upper surface of the clad layer 50 on an outer periphery of the heater layer 74.

The heater layer 74 may be provided on the insulating layer 72 of the DBR region 14. The heater layer 74 may be provided in the first trench 54. The first trench 54 may have a depth of about 10 μm. The heater layer 74 may have a reverse mesa structure.

The heater layer 74 may include chrome (Cr) and gold (Au) alloys, platinum (Pt), or the like. The heater layer 74 may tune an oscillation wavelength of the laser light 102 in the DBR region 14 by heating the clad layer 50 and the second lattice 30 using a heating voltage. The second lattice 30 may reflect the laser light 102 to the DFB region 12. The second lattice 30 may remove a reflective layer on a sidewall of the substrate 10 of the DBR region 14, thus reducing a length or linewidth of the laser diode 100.

Heater pads 76 may be connected to terminals on both sides of the heater layer 74. The heater pads 76 may provide a heating voltage to the heater layer 74.

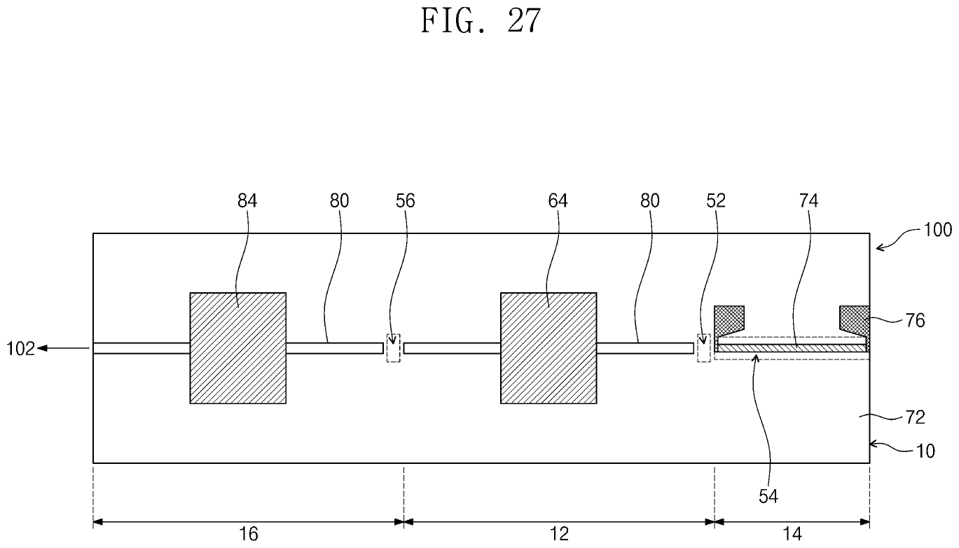

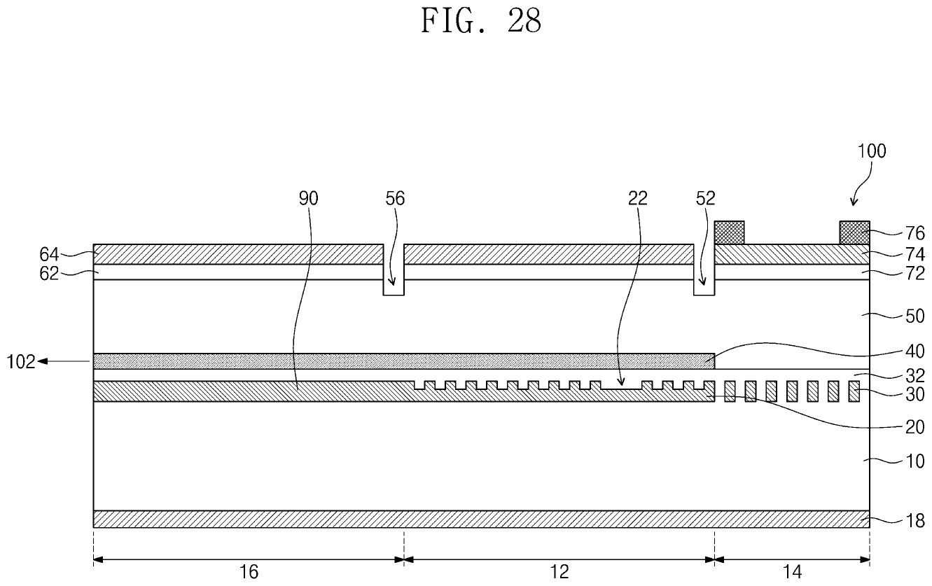

FIG. 27 illustrates an example of the distributed reflector laser diode 100 according to the inventive concept. FIG. 28 is a cross-sectional view of the distributed reflector laser diode 100 of FIG. 27.

Referring to FIGS. 27 and 28, the substrate 10 of the distributed reflector laser diode 100 according to the inventive concept may further include a semiconductor optical amplifier region 16.

The semiconductor optical amplifier region 16 may be provided on one side of the DFB region 12 facing the DBR region 14. The semiconductor optical amplifier region 16 may be a region amplifying power of the laser light 102.

A waveguide 90 may be provided on the substrate of the semiconductor optical amplifier region 16. The laser light 102 may be delivered through the waveguide 90.

The spacer layer 32 may be provided on the waveguide 90. The active layer 40 may be provided on the waveguide 90 of the semiconductor optical amplifier region 16.

The clad layer 50 may have a second electrode isolation part 56. The second electrode isolation part 56 may isolate electrodes of the DFB region 12 and the semiconductor optical amplifier region 16 on two sides of the clad layer 50. The second trench 56 may have the same depth as the first trench 52. The second trench 56 may have a depth of about 0.5 μm.

The ohmic contact layer 62 and a second upper electrode 84 may be provided on the clad layer 50 of the semiconductor optical amplifier region 16. The second upper electrode 84 may be provided on the ohmic contact layer 62. When a bias voltage is provided to the second upper electrode 84, an electric field may be generated between the second upper electrode 84 and the lower electrode 18. The active layer 40 may amplify the power of the laser light 102 in proportion to introduced current.

The substrate 10, the first lattice 20, the second lattice 30, the active layer 40, the clad layer 50, the first upper electrode 64, and the heater layer 74 of the DFB region 12 and DBR region 14 may be configured in the same manner as illustrated in FIGS. 1 and 2.

A method for manufacturing the distributed reflector laser diode 100 of the inventive concept configured as described above is described below.

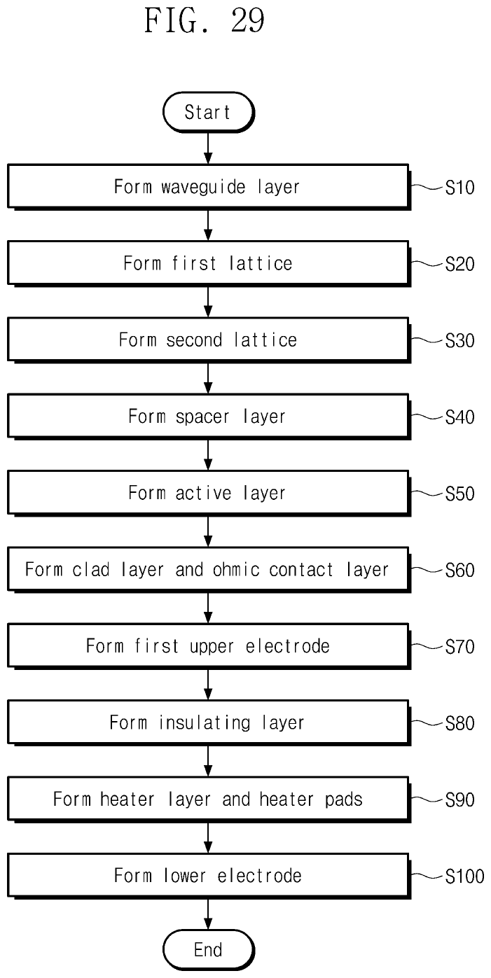

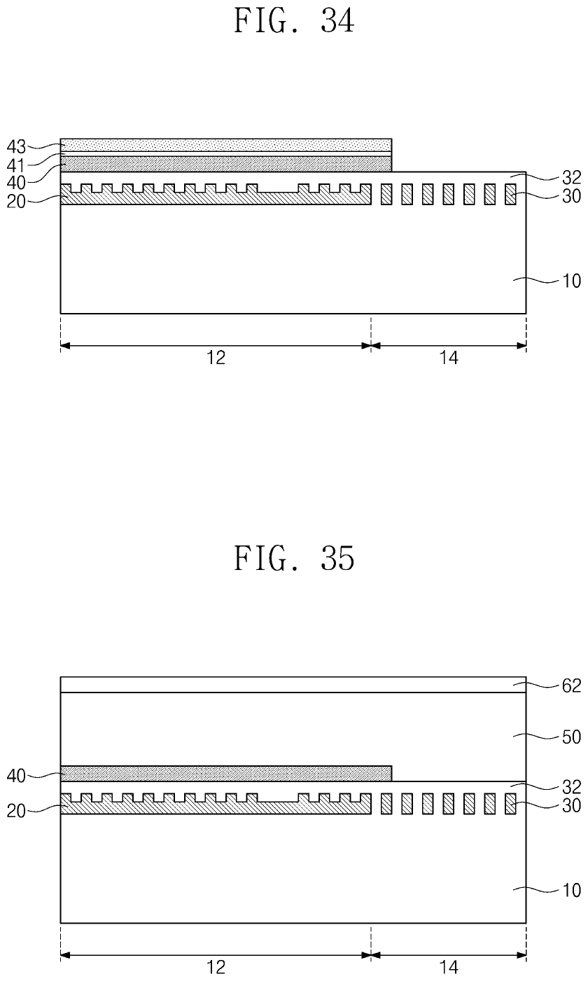

FIG. 29 illustrates a method for manufacturing the distributed reflector laser diode 100 according to the inventive concept. FIGS. 30 to 35 are cross-sectional views illustrating a manufacturing process of the distributed reflector laser diode 100 according to the inventive concept.

Referring to FIGS. 29 and 30, the waveguide layer 21 and the first cap layer 23 are formed on the substrate 10. The waveguide layer 21 may include InGaAsP of 1.0 to 1.3 μm composition. The waveguide layer 21 may have a thickness of about 30 to 300 nm. The first cap layer 23 may be formed on the waveguide layer 21. The first cap layer 23 may include p-type InP. The first cap layer 23 may have a thickness of about 20 nm. The substrate 10 may have the DFB region 12 and the DBR region 14.

Referring to FIGS. 29 and 31, the first lattice 20 is formed on the substrate of the DFB region 12 by partially removing the waveguide layer 21 and the first cap layer 23 using an e-beam lithography process and etching process. A grating pattern 27 is formed in the DFB region 12 and the DBR region 14 using an e-beam lithography process after forming the first hard mask 25 on the first cap layer 23. The first lattice 20 layer may be formed by etching the first hard mask 25 and etching the first cap layer 23 and the waveguide layer 21 after forming the grating pattern 27. The first lattice 20 layer may have a thickness of about 20 to 40 nm. The first lattice 20 may be formed through an etching process in which the first hard mask 25 and the first grating pattern 27 on the first cap layer 23 are used as a mask. The first hard mask 25 may include silicon nitride. The first lattice 20 may include InGaAsP of 1.0 to 1.3 μm composition.

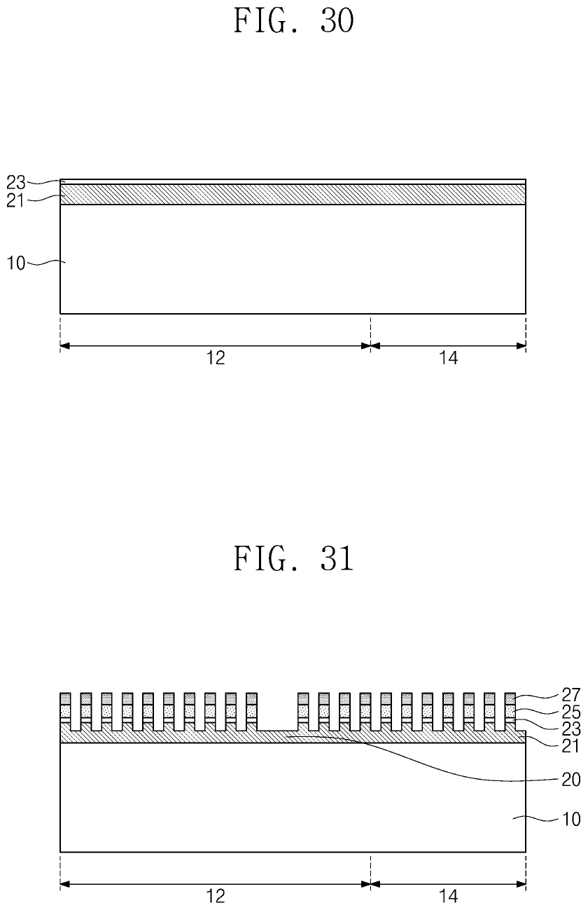

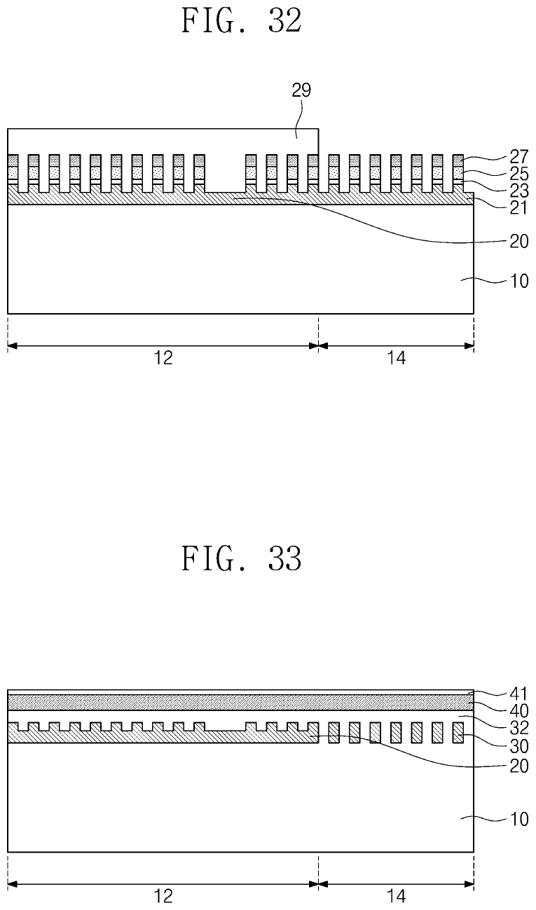

Referring to FIGS. 29 and 32, a second hard mask 29 capable of protecting the first lattice 20 portion of the DFB region 12 may be formed through photolithography after forming a hard mask to protect the first lattice 20 of the DFB region 12. The second lattice 30 is formed by partially removing the waveguide layer 21 of the DBR region 14 using an etching process in which the second hard mask 29 is used. The second lattice 30 may be deeper than the first lattice 20.

Referring to FIGS. 29 and 33, the spacer layer 32 is formed on the first lattice 20 and the second lattice 30 (S40).

Referring to FIGS. 29, 33, and 34, the active layer 40 is formed on the spacer layer 32 of the DFB region 12 (S50). A second cap layer 41 may be formed on the active layer 40. The active layer 40 may be optionally formed on the substrate 10 of the DFB region 12 through a deposition process, lithography process, and etching process. The etching process of the active layer 40 may be performed using the third hard mask 43 as an etching mask. The third hard mask 43 may include silicon nitride. The spacer layer 32 of the DBR region 14 may be exposed. The active layer 40 may include a multi quantum well (MQW) active layer. Thereafter, the third hard mask 43 may be removed.

Referring to FIGS. 29 and 35, the clad layer 50 and the ohmic contact layer 62 are formed on the active layer 40 and the spacer layer 32 (S60).

Referring to FIGS. 26 and 29, the first upper electrode 64 is formed on the ohmic contact layer 62 of the DFB region 12 (S70).

Next, the clad layer 50 is exposed by removing the ohmic contact layer 62 of the DBR region 14, and the insulating layer 72 is formed on the clad layer 50 of the DBR region 14 (S80). The insulating layer 72 may include a dielectric of silicon oxide or silicon nitride.

Next, the heater layer 74 and the heater pads 76 are formed on the insulating layer 72 of the DBR region 14 (S90).

Furthermore, the lower electrode 18 is formed on a lower surface of the substrate 10 (S100).

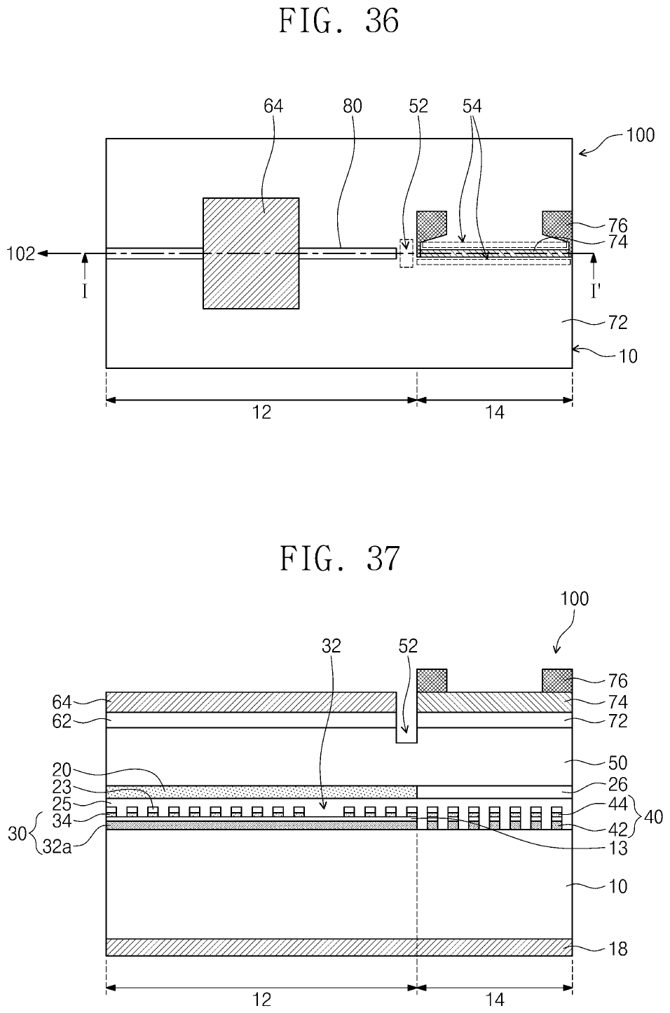

FIG. 36 illustrates an example of the distributed reflector laser diode 100 according to the inventive concept. FIG. 37 is a cross-sectional view taken along line I-I′ of FIG. 36.

Referring to FIGS. 36 and 37, the distributed reflector laser diode 100 according to the inventive concept may include a butt coupled waveguide laser diode. According to an example, the distributed reflector laser diode 100 according to the inventive concept may include a substrate 10, a first lattice 30, a second lattice 40, an active waveguide layer 20, a passive waveguide layer 26, an upper clad layer 50, a first upper electrode 64, and a heater layer 74.

The substrate 10 may include n-type InP. A lower electrode 18 may be provided under the substrate 10. According to an example, the substrate 10 may have a distributed feed-back (DFB) region 12 and a distributed Bragg reflection (DBR) region 14. The DFB region 12 may be provided to one side of the substrate 10. The DBR region 14 may be provided to the other side of the substrate 10 facing the DFB region 12.

The first lattice 30 may be provided on the substrate 10 of the DFB region 12. For example, the first lattice 30 may include InGaAsP. According to an example, the first lattice 30 may include a first lower lattice 32a and a first upper lattice 34. The first lattice 30 may extend in one direction within the DFB region 12. The first upper lattice 34 may be provided on the first lower lattice 32a. The first upper lattice 34 may be a λ/4-shifted DFB lattice. According to an example, the first upper lattice 34 may have a λ/4 phase shifter 32. The λ/4 phase shifter 32 may increase single-mode oscillation of the laser light 102. The λ/4 phase shifter 32 may tune or adjust a peak wavelength of the laser light 102.

The second lattice 40 may be provided on the substrate 10 of the DBR region 14. The first lattice 30 and the second lattice 40 may be single integrated on the substrate 10. The second lattice 40 may be provided adjacent to the first lattice 30. The second lattice 40 may have the same thickness as that of the first lattice 30. The second lattice 40 may increase reflection efficiency of the laser light 102. The second lattice 40 may have the same material as that of the first lattice 30. For example, the second lattice 40 may include InGaAsP. The second lattice 40 may remove and/or replace a reflective layer on a sidewall of the substrate 10 of the DBR region 14, thus reducing a length or linewidth of the laser diode 100. According to an example, the second lattice 40 may include a second lower lattice 42 and a second upper lattice 44. The second lower lattice 42 may be provided adjacent to the first lower lattice 32a. The second upper lattice 44 may be provided on the second lower lattice 42. The second upper lattice 44 may be aligned with the second lower lattice 42.

A first spacer layer 13 may be provided between the first lower lattice 32a and the first upper lattice 34. The first spacer layer 13 may be provided between the second lower lattice 42 and the second upper lattice 44. The first spacer layer 13 may include N-type doped InP.

A second spacer layer 23 may be provided on the first upper lattice 34 and the second upper lattice 44. The second spacer layer 23 may include N-type doped InP.

A third spacer layer 25 may be provided on the second spacer layer 23. The third spacer layer 25 may include N-type doped InP.

The active waveguide layer 20 may be provided on the third spacer layer 25 of the DFB region 12. The active waveguide layer 20 may obtain a gain of laser light 102. For example, the active waveguide layer 20 may include a multi quantum well (MQW) active layer. The laser light 102 may have a wavelength of about 1.3 μm.

The passive waveguide layer 26 may be provided on the third spacer layer 25 of the DBR region 14. The passive waveguide layer 26 may include InGaAsP. The passive waveguide layer 102 may transmit the laser light 102.

The upper clad layer 50 may be provided on the active waveguide layer 20 and the passive waveguide layer 26. The clad layer 50 may include low concentration p-type InP. The upper clad layer 50 may have a first trench 52 and a second trench 54. The first trench 52 of the upper clad layer 50 may be provided between the DFB region 12 and the DBR region 14. The second trench 54 may be formed along an outer periphery of the heater layer 74 on the upper clad layer 50. For example, the first trench 52 and the second trench 54 each may have a depth of about 0.5 μm. According to an example, the upper clad layer 50 may have a mesa structure or ridge waveguide structure within the DFB region 12. The upper clad layer 50 in the DFB region 12 may be expressed as an optical waveguide 80. The upper clad layer 50 outside the optical waveguide 80 may have a depth of about 4 μm to about 5 μm.

An ohmic contact layer 62 may be provided on the upper clad layer 50 of the DFB region 12. The ohmic contact layer 62 may be provided on the optical waveguide 80 of the upper clad layer 50. The ohmic contact layer 62 may include high concentration p-type InGaAs.

The first upper electrode 64 may be provided on the ohmic contact layer 62. The first upper electrode 64 may include metal such as gold (Au), silver (Ag), copper (Cu), aluminum (Al), or tungsten (W). The first upper electrode 64 may obtain a gain of the laser light 102 by providing an electric field in the optical waveguide 80 using an external bias voltage.

An insulating layer 72 may be provided on the upper clad layer 50 of the DBR region 14. The insulating layer 72 may be provided on an upper surface of the upper clad layer 50 on an outer periphery of the heater layer 74.

The heater layer 74 may be provided on the insulating layer 72 of the DBR region 14. The heater layer 74 may be provided in the second trench 54. The second trench 54 may have a depth of about 10 μm. The heater layer 74 may have a reverse mesa structure. The heater layer 74 may include chrome and nickel alloys. The heater layer 74 may tune an oscillation wavelength of the laser light 102 in the DBR region 14 by heating the upper clad layer 50 and the second lattice 40 using a heating voltage. The second lattice 40 may reflect the laser light 102 to the DFB region 12. The second lattice 40 may remove a reflective layer on a sidewall of the substrate 10 of the DBR region 14, thus reducing a length or linewidth of the laser diode 100.

Heater pads 76 may be connected to terminals on both sides of the heater layer 74. The heater pads 76 may provide a heating voltage to the heater layer 74.

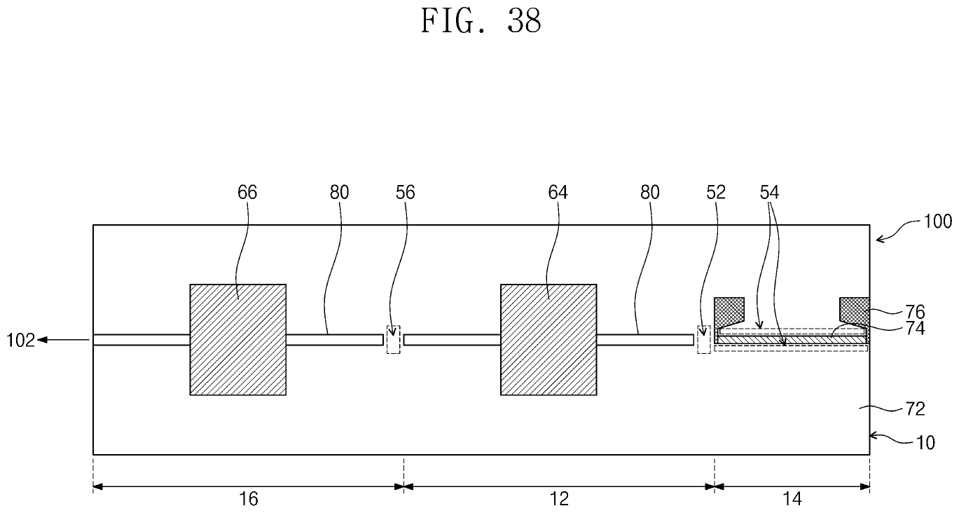

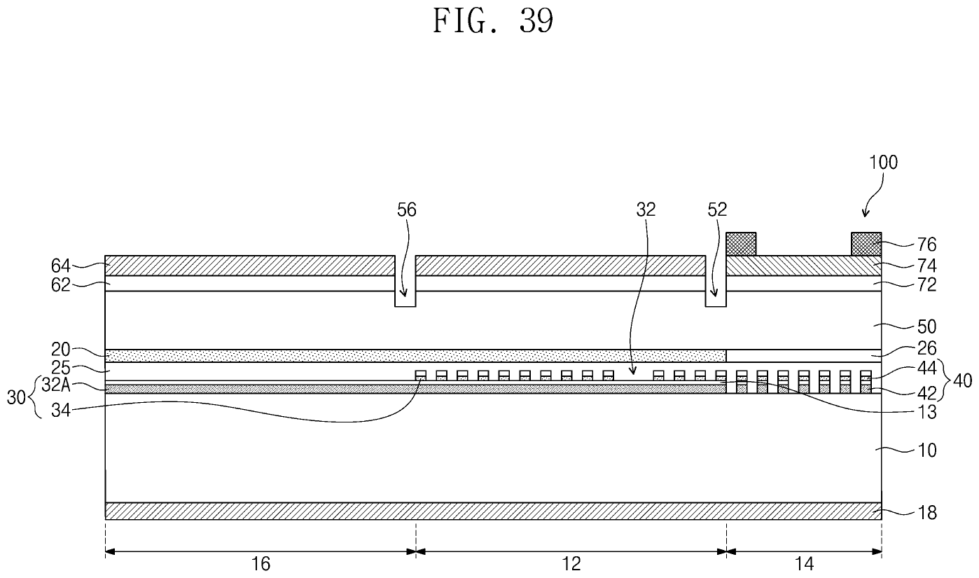

FIG. 38 illustrates an example of the distributed reflector laser diode 100 according to the inventive concept. FIG. 39 is a cross-sectional view of the distributed reflector laser diode 100 of FIG. 38.

Referring to FIGS. 38 and 39, the substrate 10 of the distributed reflector laser diode 100 according to the inventive concept may further include a semiconductor optical amplifier region 16.

The semiconductor optical amplifier region 16 may be provided on one side of the DFB region 12 facing the DBR region 14. The semiconductor optical amplifier region 16 may be a region amplifying power of the laser light 102.

The substrate 10, the first lower lattice 32a, the first spacer layer 13, the third spacer layer 25, the active waveguide layer 20, and the upper clad layer 50 may extend from the DFB region 12 to the semiconductor optical amplifier region 16.

The upper clad layer 50 may have a third trench 56. The third trench 56 may be provided between the DFB region 12 and the semiconductor optical amplifier region 16. A depth of the third trench 56 may be larger or smaller than a depth of the first trench 52. The third trench 56 may have a depth of about 0.5 μm.

The ohmic contact layer 62 and a second upper electrode 66 may be provided on the upper clad layer 50 of the semiconductor optical amplifier region 16. The second upper electrode 66 may be provided on the ohmic contact layer 62. When a bias voltage is provided to the second upper electrode 66, an electric field may be generated between the second upper electrode 66 and the lower electrode 18. The active waveguide layer 20 may amplify the power of the laser light 102 in proportion to the electric field.

The substrate 10, the first lattice 30, the second lattice 40, the first spacer layer 13, the second spacer layer 23, the third spacer layer 25, the active waveguide layer 20, the upper clad layer 50, the first upper electrode 64, the insulating layer 72, the heater layer 74, and the heater pads 76 of the DFB region 12 and DBR region 14 may be configured in the same manner as illustrated in FIGS. 1 and 2.

A method for manufacturing the distributed reflector laser diode 100 of the inventive concept configured as described above is described below.

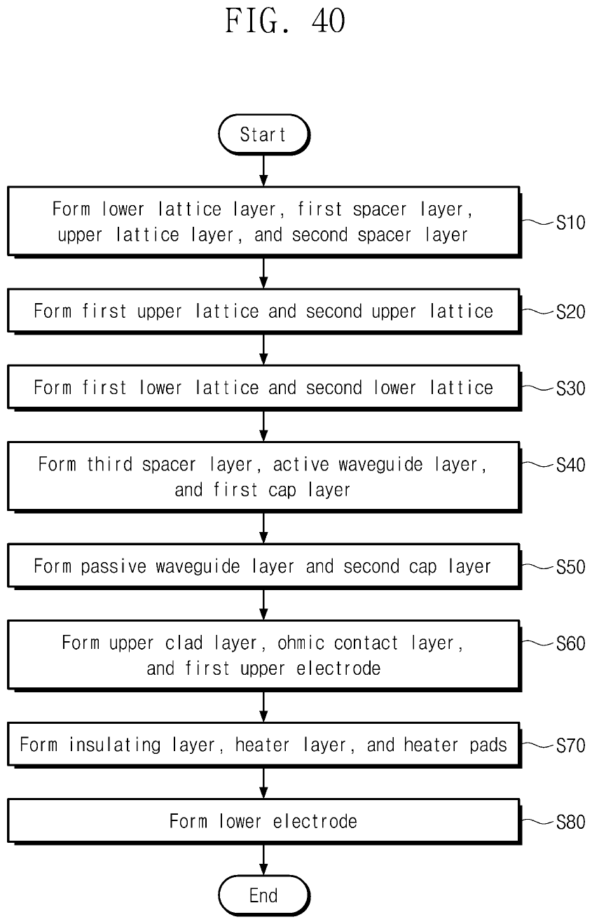

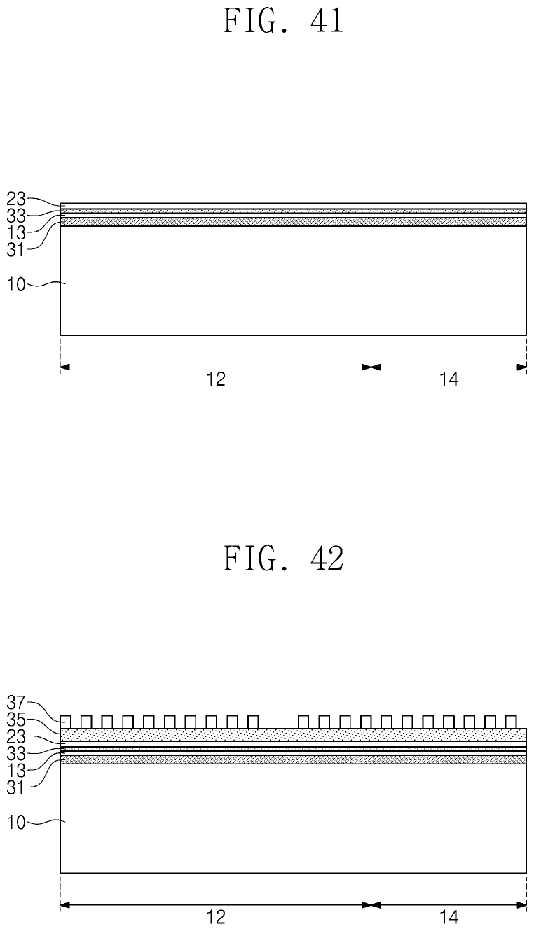

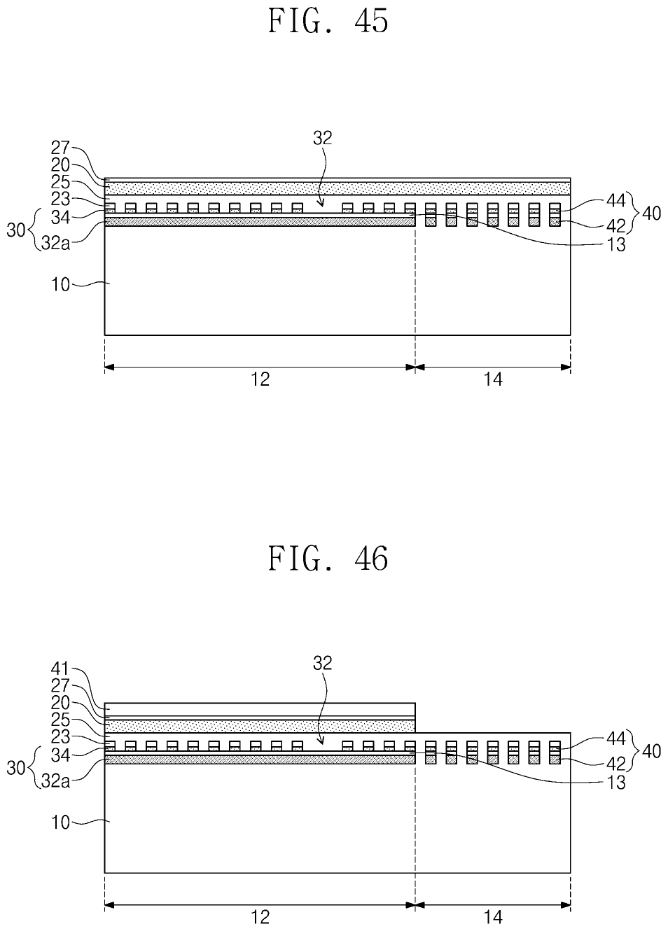

FIG. 40 illustrates a method for manufacturing the distributed reflector laser diode 100 according to the inventive concept. FIGS. 41 to 47 are cross-sectional views illustrating a manufacturing process of the distributed reflector laser diode 100 according to the inventive concept.

Referring to FIGS. 40 and 41, the lower lattice layer 31, the first spacer layer 13, the upper lattice layer 33, and the second spacer layer 23 are formed on the substrate 10 (S10). The lower lattice layer 31 may include InGaAsP. The first spacer layer 13 may be formed on the lower lattice layer 31. The first spacer layer 13 may include n-type InP. The upper lattice layer 33 may be formed on the first spacer layer 13. The upper lattice layer 33 may include InGaAsP. The second spacer layer 23 may be formed on the upper lattice layer 33. The second spacer layer 23 may include n-type InP.

Referring to FIGS. 40, 42, and 43, the first upper lattice 34 and the second upper lattice 44 are formed by partially removing the upper lattice layer 33 and the second spacer layer 23 using a first photoresist pattern 37 and a first hard mask pattern 35 as an etching mask (S20). The first upper lattice 34 may be formed in the DFB region 12, and the second upper lattice 44 may be formed in the DBR region 14.

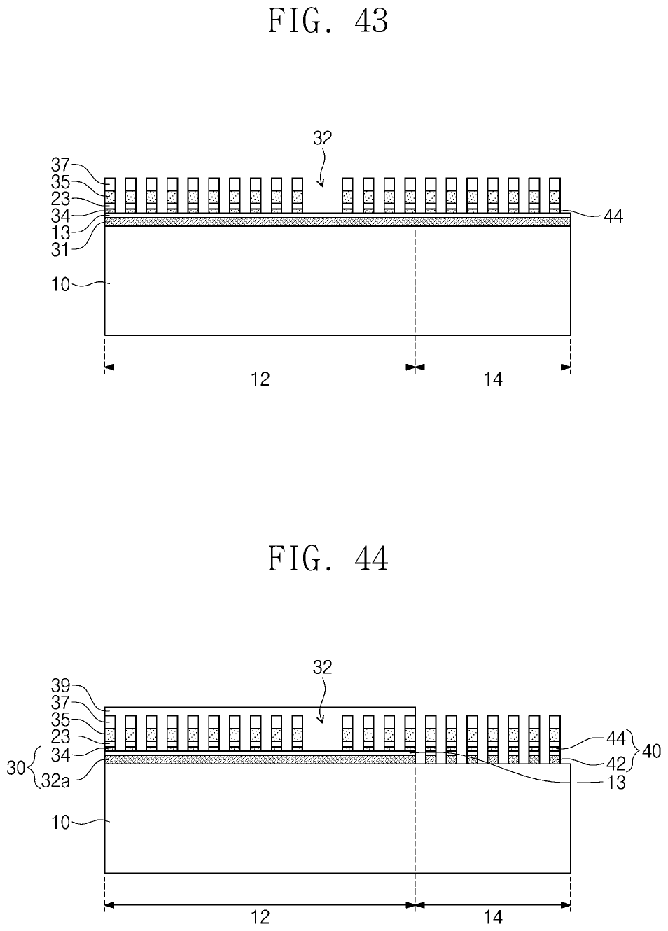

Referring to FIGS. 40 and 44, the first lower lattice 32a and the second lower lattice 42 are formed by partially removing the first spacer 13 and the lower lattice layer 31 of the DBR region 14 using a second hard mask pattern 39 as an etching mask (S30). The first lower lattice 32a may be formed in the DFB region 12, and the second lower lattice 42 may be formed in the DBR region 14.

Thereafter, the first photoresist pattern 37, the first hard mask pattern 35, and the second hard mask pattern 39 may be removed.

Referring to FIGS. 40, 45, and 46, the third spacer layer 25, the active waveguide layer 25, and the first cap layer 27 are formed on the first upper lattice 34 and the second upper lattice 44 (S40). The active waveguide layer 25 and the first cap layer 27 may be etched in the DBR region 14 using a second photoresist pattern 41 as an etching mask. The active waveguide layer 20 and the first cap layer 27 may be optionally formed in the DFB region 12. The active waveguide layer 20 may include a multi quantum well (MQW) active layer. The first cap layer 27 may include p-type InP.

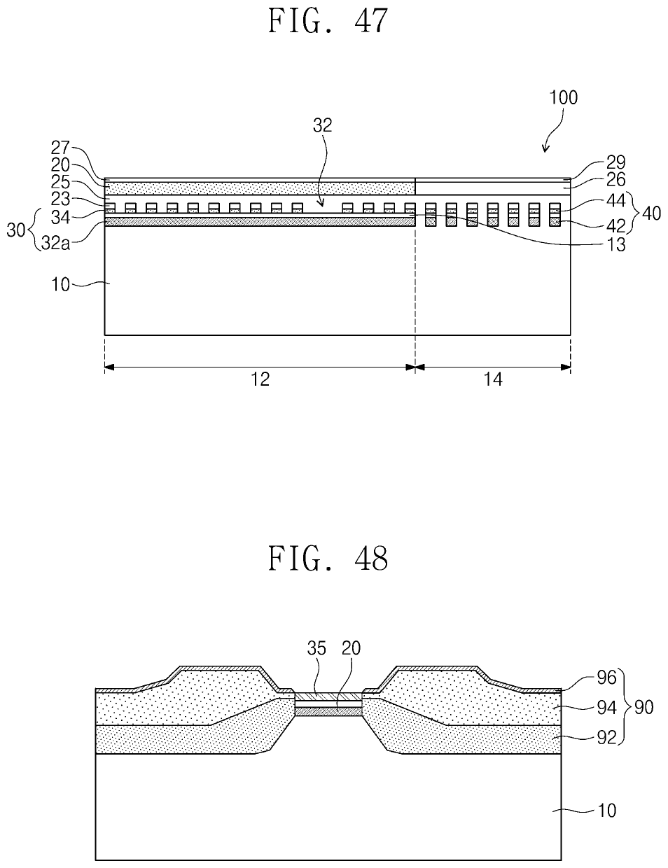

Referring to FIGS. 40 and 47, the passive waveguide layer 26 and the second cap layer 29 are formed on the third spacer layer 25 of the DBR region 14 (S50). The passive waveguides layer 26 may be in contact with the active waveguide layer 20. The passive waveguide layer 26 may include InGaAsP. The second cap layer 29 may be formed on the passive waveguide layer 26. The second cap layer 29 may include p-type InP.

Referring to FIGS. 37 and 40, the upper clad layer 50 and the ohmic contact layer 62 are formed on the passive waveguide layer 26 and the active waveguide layer 20 (S60).

Next, the first upper electrode 64 is formed on the ohmic contact layer 62 of the DFB region 12.

Next, the upper clad layer 50 is exposed by removing the ohmic contact layer 62 of the DBR region 14, and the insulating layer 72 is formed on the upper clad layer 50 of the DBR region 14 (S70). The insulating layer 72 may include a dielectric of silicon nitride or silicon oxide formed using a chemical vapor deposition method.

Thereafter, the heater layer 74 and the heater pads 76 are formed on the insulating layer 72.

Furthermore, the lower electrode 18 is formed on a lower surface of the substrate 10 (S80).

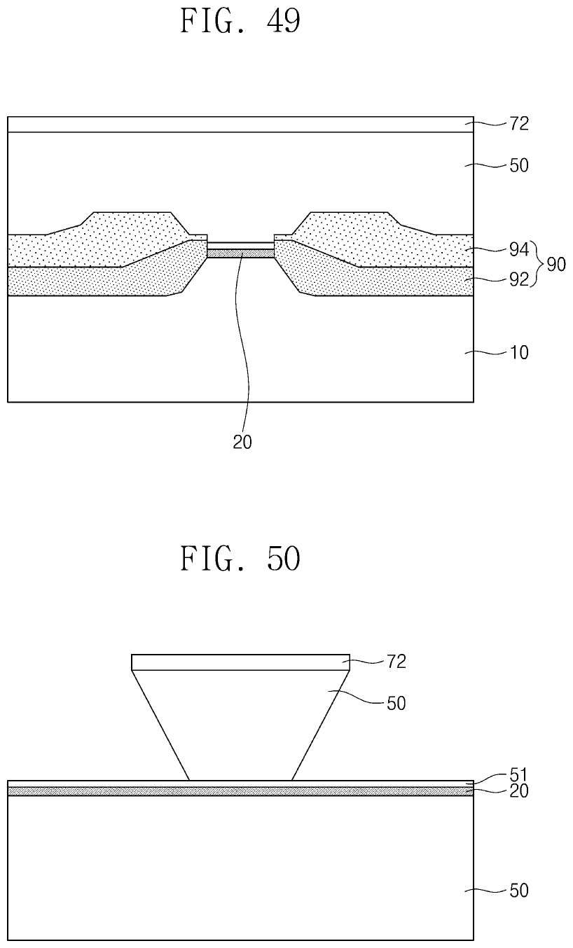

FIGS. 48 and 49 illustrate an example of a current blocking layer 90 on an outer periphery of the active waveguide layer 20 of FIG. 46.

Referring to FIGS. 48 and 49, the current blocking layer 90 may be regrown or formed on the outer periphery of the active waveguide layer 20. The current blocking layer 90 may be formed between the first lattice 30 and the upper clad layer 50 and between the second lattice 40 and the upper clad layer 50. The current blocking layer 90 may include a pnp current blocking layer. According to an example, the current blocking layer 90 may include a first p-InP 92, a first n-InP 94, and a second p-InP 96. The first p-InP 92, the first n-InP 94, and the second p-InP 96 may be sequentially formed.

FIG. 50 illustrates the ridge waveguide of the upper clad layer 50 of FIG. 37.

Referring to FIG. 50, the upper clad layer 50 may have a reverse mesa structure.

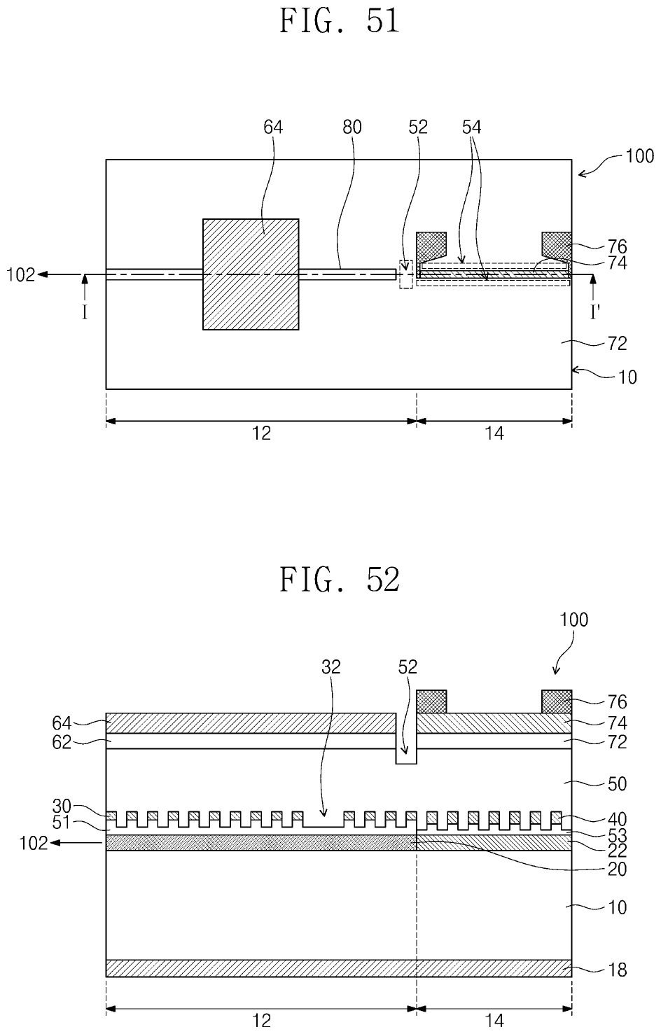

FIG. 51 illustrates an example of the distributed reflector laser diode 100 according to the inventive concept. FIG. 52 is a cross-sectional view taken along line I-I′ of FIG. 51.

Referring to FIGS. 51 and 52, the distributed reflector laser diode 100 according to the inventive concept may include a butt coupled waveguide laser diode. According to an example, the distributed reflector laser diode 100 according to the inventive concept may include a substrate 10, an active layer 20, a passive waveguide layer 22, a first lattice 30, a second lattice 40, a clad layer 50, a first upper electrode 64, and a heater layer 74.

The substrate 10 may include n-type InP. A lower electrode 18 may be provided under the substrate 10. According to an example, the substrate 10 may have a distributed feed-back (DFB) region 12 and a distributed Bragg reflection (DBR) region 14.

The active layer 20 may be provided on the substrate 10 of the DFB region 12. The active layer 20 may obtain a gain of laser light 102. For example, the active layer 20 may include a multi quantum well (MQW) active layer.

The first lattice 30 may be provided on the active layer 20 of the DFB region 12. The first lattice 30 may include 1.3 μm InGaAsP. The first lattice 30 may be a λ/4-shifted DFB lattice. According to an example, the first lattice 30 may have a λ/4 phase shifter 32. The λ/4 phase shifter 32 may increase single-mode oscillation of the laser light 102. The λ/4 phase shifter 32 may tune or adjust a peak wavelength of the laser light 102. The λ/4 phase shifter 32 may be provided at a position corresponding to ¼ of a length of the DFB region 12.

A first spacer layer 51 may be provided between the active layer 20 and the first lattice 30. The first spacer layer 51 may include p-type InP, but an embodiment of the inventive concept is not limited thereto.

The passive waveguide layer 22 may be provided on the substrate of the DBR region 14. The passive waveguide layer 20 may deliver laser light 102. For example, the passive waveguide layer 22 may include InGaAs, InGaAsP, or AlGaAs.

The second lattice 40 may be provided on the passive waveguide layer 22. The second lattice 40 may be thicker than the first lattice 30. The second lattice 40 may be deeper than the first lattice 30. The second lattice 40 may have a lower height than the active layer 20, the first spacer layer 51, and the first lattice 30. The second lattice 40 may increase reflection efficiency of the laser light 102. The second lattice 40 may have the same material as that of the first lattice 30. For example, the second lattice 40 may include 1.3 μm InGaAsP. The second lattice 40 may remove a reflective layer on a sidewall of the substrate 10 of the DBR region 14, thus reducing a length or linewidth of the laser diode 100.

A second spacer layer 53 may be provided between the passive waveguide layer 22 and the second lattice 40. The second spacer layer 53 may include the same material as that of the first spacer layer 51. The second spacer layer 53 may include p-type InP, but an embodiment of the inventive concept is not limited thereto.

The clad layer 50 may be provided on the first lattice 30 and the second lattice 40. The clad layer 50 may include low concentration p-type InP. The clad layer 50 may have a first trench 52 and a second trench 54. The first trench 52 of the clad layer 50 may be provided between the DFB region 12 and the DBR region 14. The second trench 54 may be formed along an outer periphery of the heater layer 70 on the clad layer 50. According to an example, the clad layer 50 may have a mesa structure or ridge waveguide structure within the DFB region 12. The clad layer 50 in the DFB region 12 may be expressed as an optical waveguide 80. The clad layer 50 outside the optical waveguide 80 may have a depth of about 2 μm to about 5 μm.

An ohmic contact layer 62 may be provided on the clad layer 50 of the DFB region 12. The ohmic contact layer 62 may be provided on the optical waveguide 80 of the clad layer 50. The ohmic contact layer 62 may include high concentration p-type InGaAs.

The first upper electrode 64 may be provided on the ohmic contact layer 62. The first upper electrode 64 may include metal such as gold (Au), silver (Ag), copper (Cu), aluminum (Al), or tungsten (W). The first upper electrode 64 may obtain a gain of the laser light 102 by providing an electric field in the optical waveguide 80 using an external bias voltage.

An insulating layer 72 may be provided on the clad layer 50 of the DBR region 14. The insulating layer 72 may be provided on an upper surface of the clad layer 50 and under the heater layer 74.

The heater layer 74 may be provided on the insulating layer 72 of the DBR region 14. The heater layer 74 may be provided in the second trench 54. The second trench 54 may have a depth of about 10 μm. The heater layer 74 may have a reverse mesa structure.

The heater layer 74 may include metal such as chrome, platinum, and gold and alloys thereof. The heater layer 74 may tune an oscillation wavelength of the laser light 102 in the DBR region 14 by heating the clad layer 50 and the second lattice 40 using a heating voltage. The second lattice 40 may reflect the laser light 102 to the DFB region 12. The second lattice 40 may remove a reflective layer on a sidewall of the substrate 10 of the DBR region 14, thus reducing a length or linewidth of the laser diode 100.

Heater pads 76 may be connected to terminals on both sides of the heater layer 74. The heater pads 76 may provide a heating voltage to the heater layer 74.

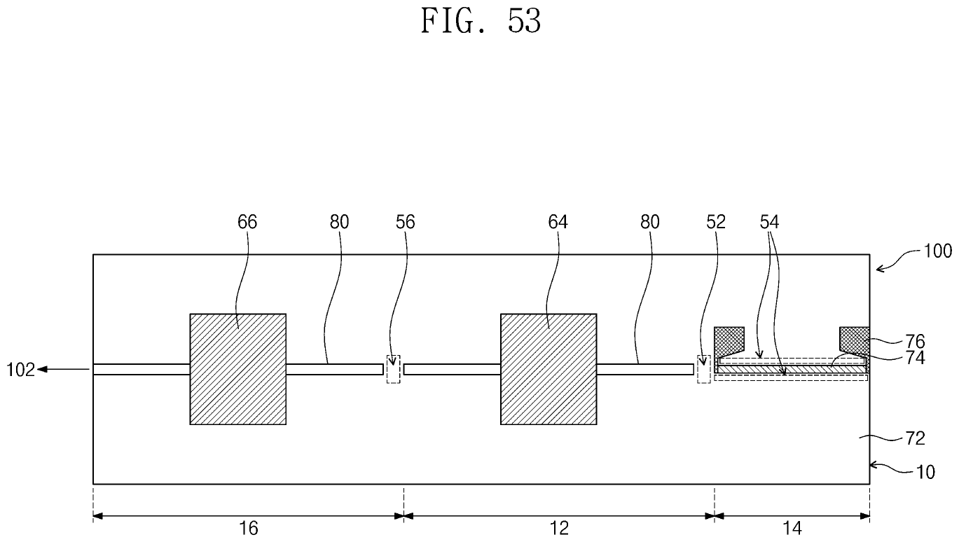

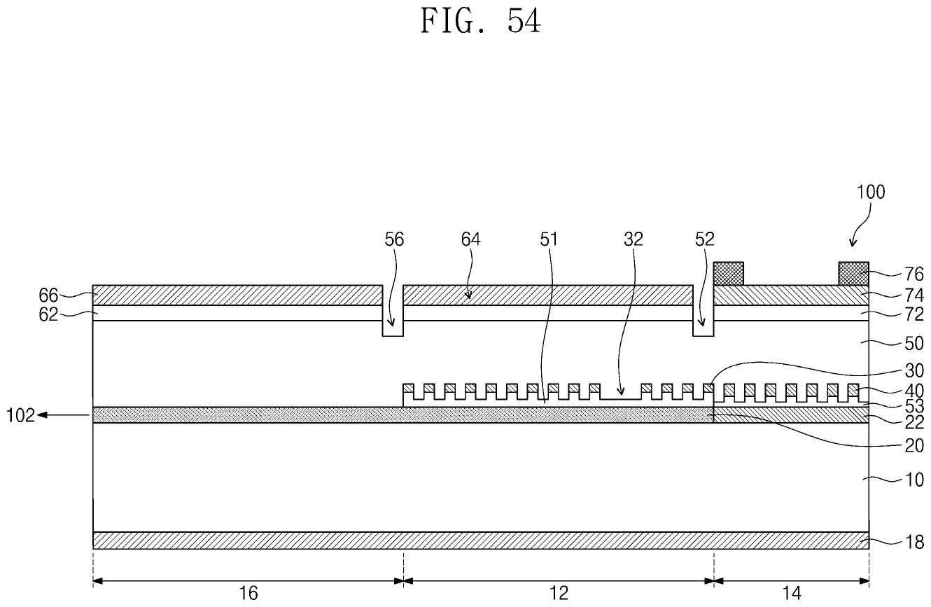

FIG. 53 illustrates an example of the distributed reflector laser diode 100 according to the inventive concept. FIG. 54 is a cross-sectional view of the distributed reflector laser diode 100 of FIG. 53.

Referring to FIGS. 53 and 54, the substrate 10 of the distributed reflector laser diode 100 according to the inventive concept may further include a semiconductor optical amplifier region 16.

The semiconductor optical amplifier region 16 may be provided on one side of the DFB region 12 facing the DBR region 14. The semiconductor optical amplifier region 16 may be a region amplifying power of the laser light 102.

The active layer 20 may extend from the DFB region 12 to the semiconductor optical amplifier region 16.

The clad layer 50 may have a third trench 56. The third trench 56 may divide two sides of the clad layer 50 into the DFB region 12 and the semiconductor optical amplifier region 16. The third trench 56 may have a smaller depth than the first trench 52. The third trench 56 may have a depth of about 0.5 μm.

The ohmic contact layer 62 and a second upper electrode 66 may be provided on the clad layer 50 of the semiconductor optical amplifier region 16. The second upper electrode 66 may be provided on the ohmic contact layer 62. When a bias voltage is provided to the second upper electrode 66, an electric field may be generated between the second upper electrode 66 and the lower electrode 18. The active layer 20 may amplify the power of the laser light 102 in proportion to the electric field.

The substrate 10, the active layer 20, the passive waveguide layer 22, the first lattice 30, the second lattice 40, the clad layer 50, the first upper electrode 64, and the heater layer 74 of the DFB region 12 and DBR region 14 may be configured in the same manner as illustrated in FIGS. 1 and 2.

A method for manufacturing the distributed reflector laser diode 100 of the inventive concept configured as described above is described below.

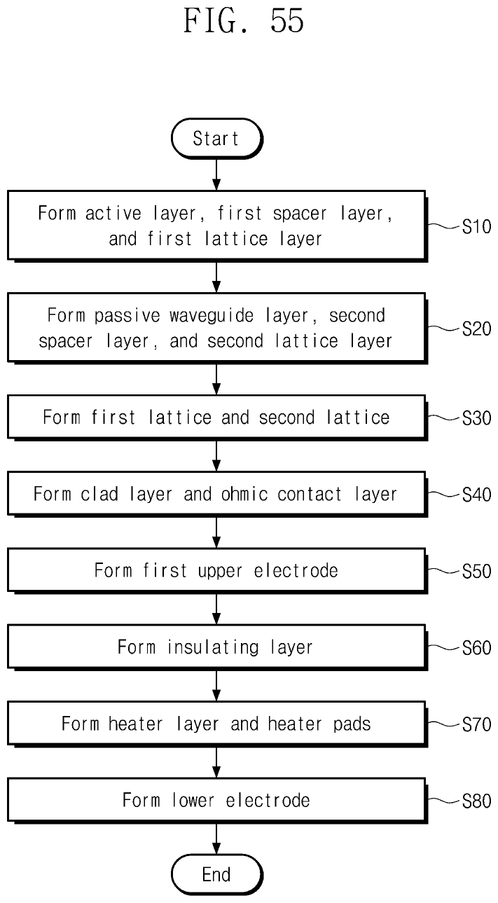

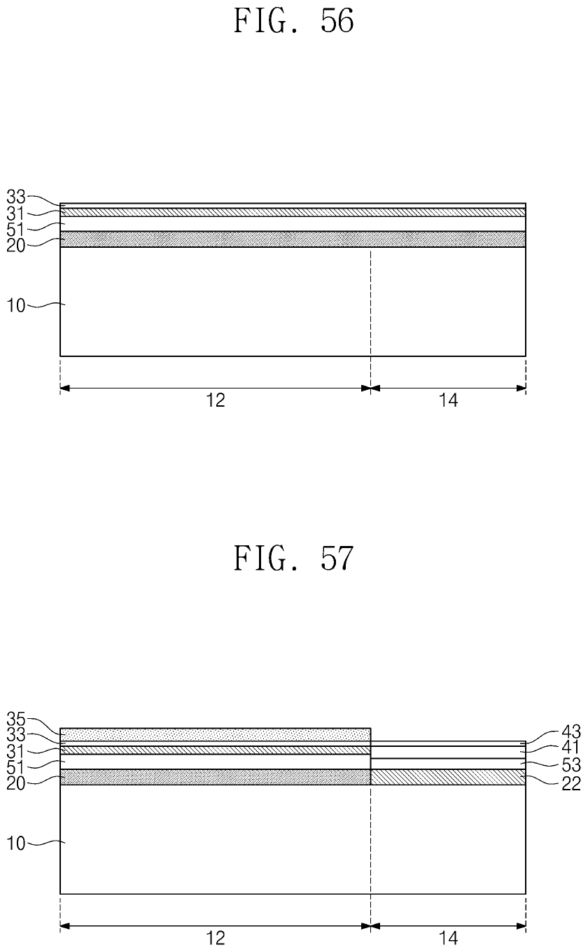

FIG. 55 illustrates a method for manufacturing the distributed reflector laser diode 100 according to the inventive concept. FIGS. 56 to 62 are cross-sectional views illustrating a manufacturing process of the distributed reflector laser diode 100 according to the inventive concept.

Referring to FIGS. 55 and 56, the active layer 20, the first spacer layer 51, the first lattice layer 31, and the first cap layer 33 are formed on the substrate 10 (S10). The active layer 20 may be formed on the substrate 10. The active layer 20 may include a multi quantum well (MQW) active layer. The first spacer layer 51 may be formed on the active layer 20. The first spacer layer 51 may include p-type InP, but an embodiment of the inventive concept is not limited thereto. The first lattice layer 31 may be formed on the spacer layer 51. The first lattice layer 31 may include InGaAsP of 1.3 μm composition. The first lattice layer 31 may have a thickness of about 300 nm. The first cap layer 33 may be formed on the first lattice layer 31. The first cap layer 33 may include p-type InP. The first cap layer 33 may have a thickness of about 20 nm. A first hard mask film 35 (FIG. 7) may be formed on the first cap layer 33. The first hard mask film 35 may include silicon nitride.

Referring to FIGS. 55 and 57, the substrate 10 is exposed by partially removing the active layer 20, the first spacer layer 51, the first lattice layer 31, and the first cap layer 33 of the DBR region 14 using the first hard mask film 35 as an etching mask, and the passive waveguide layer 22, a second spacer layer 53, a second lattice layer 41, and a second cap layer 43 are sequentially formed (S20). The passive waveguide layer 22 may include InGaAs, InGaAsP, or AlGaAs. The second lattice layer 41 may be formed through butt regrowth. The second lattice layer 41 may have the same material as that of the first lattice layer 31. The second lattice layer 41 may include InGaAsP of 1.3 μm composition. The second cap layer 43 may be formed on the second lattice layer 41. The second cap layer 43 may have the same material as that of the first cap layer 33. The second cap layer 43 may include p-type InP. A second hard mask film 45 may be formed on the second cap layer 43. The second hard mask film 45 may include silicon nitride (SiN).

Referring to FIGS. 55 and 58 to 61, the first lattice 30 and the second lattice 40 are formed by partially removing the first lattice layer 31, the second lattice layer 41, and the second cap layer 43 using a grating process and etching process (S30).

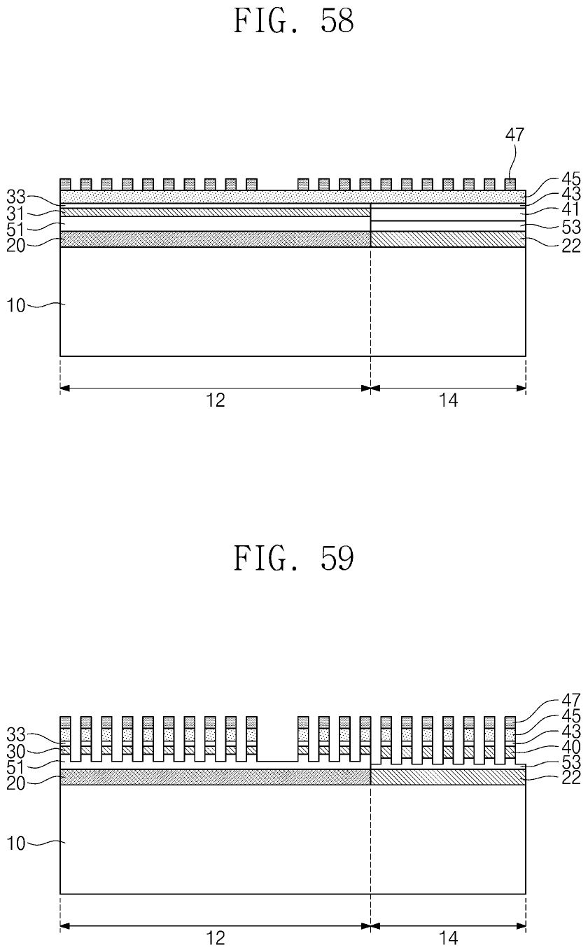

Referring to FIGS. 58 and 59, the first lattice 30 may be formed through an etching process in which the first hard mask film 35 and a first lattice pattern 47 are used as an etching mask. The first lattice pattern 47 may be formed through an e-beam lithography process. The first lattice layer 31, the first cap layer 33, the second lattice layer 41, the second cap layer 43, and the second hard mask film 45 may be patterned using the first lattice pattern 47 as an etching mask. That is, the first lattice 30, the second lattice 40, the first cap layer 33, and the second cap layer 43 may be formed through an etching process. The first spacer layer 51 and the second spacer layer 53 may be used as an etch stop layer during an etching process of the first lattice layer 31, the first cap layer 33, the second lattice layer 41, and the second cap layer 43. The first cap layer 33, the second cap layer 43, the second hard mask film 45, and the first lattice pattern 47 may be removed.

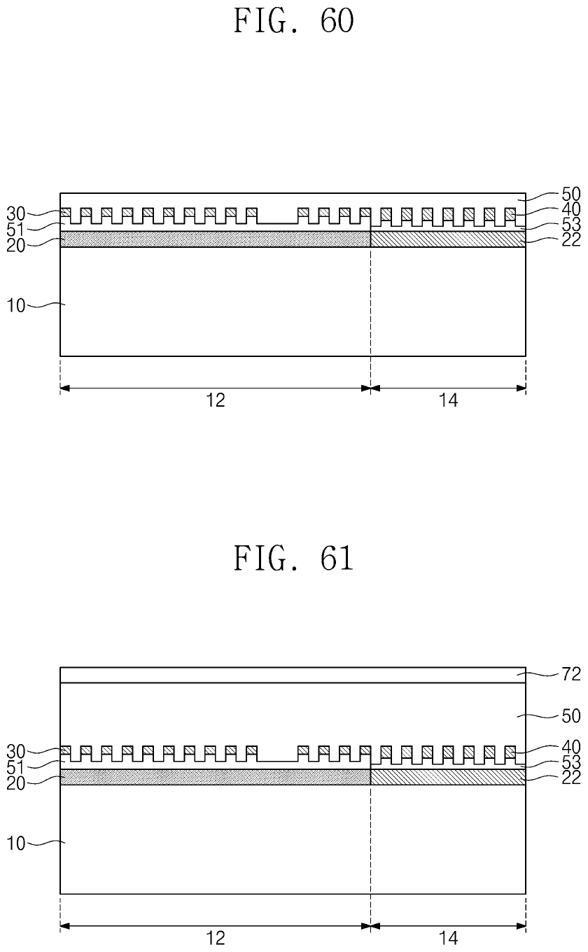

Referring to FIGS. 60 and 61, the clad layer 50 and the ohmic contact layer 62 are formed on the first lattice 30 and the second lattice 40 (S40).

Referring to FIGS. 52 and 55, the first upper electrode 64 is formed on the ohmic contact layer 62 of the DFB region 12 (S50).

Next, the clad layer 50 is exposed by removing the ohmic contact layer 62 of the DBR region 14, and the insulating layer 72 is formed on the clad layer 50 of the DBR region 14 (S60). The insulating layer 72 may include a dielectric of silicon oxide or silicon nitride.

Next, the heater layer 74 and the heater pads 76 are formed on the insulating layer 72 of the DBR region 14 (S70).

Furthermore, the lower electrode 18 is formed on a lower surface of the substrate 10 (S80).

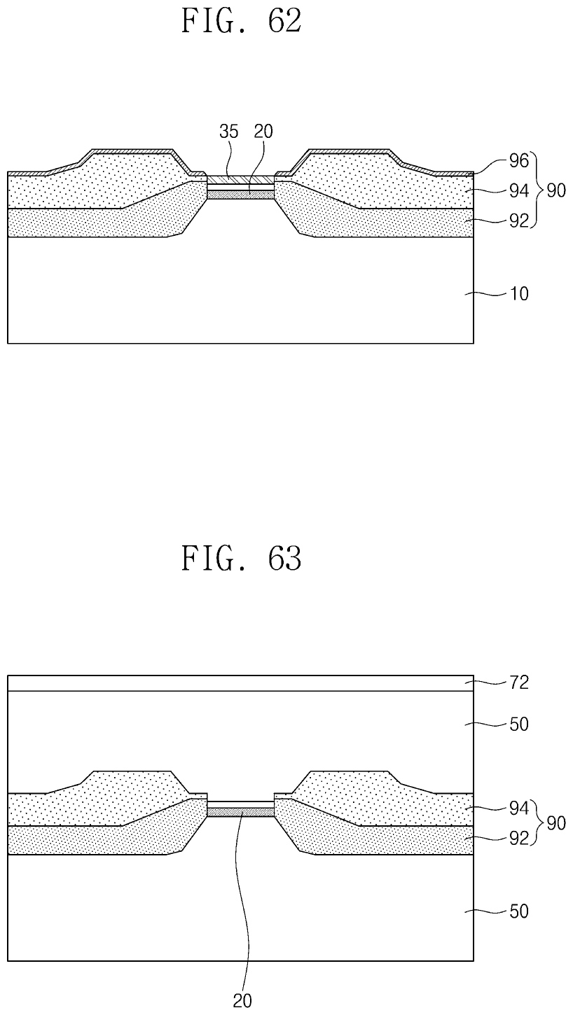

FIGS. 62 and 63 illustrate an example of a current blocking layer 90 on an outer periphery of the active layer 20 and the first hard mask film 35 of FIG. 57.

Referring to FIGS. 62 and 63, the current blocking layer 90 may be regrown or formed on the outer periphery of the active layer 20 and the first hard mask film 35. The current blocking layer 90 may be formed between the first lattice 30 and the clad layer 50 and between the second lattice 40 and the clad layer 50. The current blocking layer 90 may include a pnp current blocking layer. According to an example, the current blocking layer 90 may include a first p-InP 92, a first n-InP 94, and a second p-InP 96. The first p-InP 92, the first n-InP 94, and the second p-InP 96 may be sequentially formed.

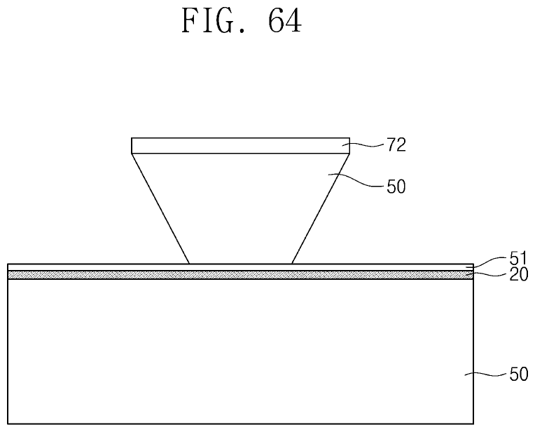

FIG. 64 illustrates the ridge waveguide of the clad layer 50 of FIG. 52.

Referring to FIG. 64, the clad layer 50 may have a reverse mesa structure.

As described above, the distributed reflector laser diode according to the inventive concept may be provided with a small length and low linewidth by increasing reflection efficiency of laser light using a second lattice that is provided in a DBR region and thicker than a first lattice in a DFB region.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A distributed reflector laser diode comprising:
a substrate including a distributed feed-back (DFB) region and a distributed Bragg reflection (DBR) region contacting the DFB region;
an active layer on the substrate of the DFB region;
a first lattice on the active layer;
a second lattice provided on the substrate of the DBR region and thicker than the first lattice;
an upper clad layer on the first lattice and the second lattice;
an ohmic contact layer on the upper clad layer of the DFB region;
an upper electrode on the ohmic contact layer;
an insulating layer on the clad layer of the DBR region; and
a heater layer on the insulating layer.

2. The distributed reflector laser diode of claim 1, further comprising a lower spacer layer provided between the active layer and the substrate.

3. The distributed reflector laser diode of claim 2, further comprising a lower clad layer provided between the lower spacer layer and the substrate.

4. The distributed reflector laser diode of claim 3, wherein the lower clad layer has the same thickness as that of the second lattice.

5. The distributed reflector laser diode of claim 2, further comprising an upper spacer layer provided between the first lattice and the active layer.

6. The distributed reflector laser diode of claim 5, wherein the upper spacer layer has the same thickness as that of the lower spacer layer.

7. The distributed reflector laser diode of claim 5, wherein the lower spacer layer, the upper spacer layer, and the upper clad layer each include indium phosphide (InP).

8. The distributed reflector laser diode of claim 1, wherein the active layer includes a multi quantum well (MQW) active layer.

9. The distributed reflector laser diode of claim 1, wherein the upper clad layer includes a first trench between the DFB region and the DBR region and a second trench on an outer periphery of the heater layer.

10. The distributed reflector laser diode of claim 9, wherein the substrate further includes a semiconductor optical amplifier region on one side of the DFB region facing the DBR region.

11. A distributed reflector laser diode comprising:
a substrate including a distributed feed-back (DFB) region and a distributed Bragg reflection (DBR) region contacting the DFB region;
a lower clad layer on the substrate of the DFB region;
an active layer on the lower clad layer;
a first lattice on the active layer;
a second lattice on the substrate of the DFB region;
an upper clad layer between the first lattice and the second lattice;
an upper electrode on the upper clad layer of the DFB region; and
a heater layer on the upper clad layer of the DBR region.

12. The distributed reflector laser diode of claim 11, wherein the first lattice includes:
a first lower lattice in the lower clad layer; and
a first upper lattice in the upper clad layer.

13. The distributed reflector laser diode of claim 12, wherein the first lattice further includes a first intermediate lattice in the active layer between the first lower lattice and the first upper lattice.

14. The distributed reflector laser diode of claim 13, wherein the second lattice includes:
a second lower lattice adjacent to the first lower lattice;
a second intermediate lattice provided on the second lower lattice and adjacent to the first intermediate lattice; and
a second upper lattice provided on the second intermediate lattice and adjacent to the first upper lattice.

15. The distributed reflector laser diode of claim 14,
wherein the first lower lattice, the first intermediate lattice, and the first upper lattice are discontinuously arranged in a direction perpendicular to the substrate, and
the second lower lattice, the second intermediate lattice, and the second upper lattice are continuously arranged in a direction perpendicular to the substrate.

16. A method for manufacturing a distributed reflector laser diode, the method comprising:
sequentially forming a lower clad layer, a lower spacer layer, an active layer, an upper spacer layer, a first lattice layer, and a first cap layer on a substrate including a distributed feed-back (DFB) region and a distributed Bragg reflection (DBR) region contacting the DFB region;
exposing the lower spacer layer by removing the active layer, the upper spacer layer, the first lattice layer, and the first cap layer from the DBR region;
forming a first lattice by partially removing the first cap layer, the upper spacer layer, and the first lattice layer of the DFB region;
forming a second lattice by partially removing the lower clad layer of the DBR region;
forming an upper clad layer on the first lattice and the second lattice;
forming an ohmic contact layer and an upper electrode on the upper clad layer of the DFB region; and
forming an insulating layer and a heater layer on the upper clad layer of the DBR region.

17. The method of claim 16, wherein the first lattice is formed through an etching process in which a first photoresist pattern and a first hard mask film are used as an etching mask.

18. The method of claim 17, further comprising forming a second hard mask film on the first photoresist pattern and the first hard mask film of the DFB region.

19. The method of claim 18, wherein the second lattice is formed through an etching process of the lower clad layer using the first photoresist pattern, the first hard mask film, and the second hard mask film as an etching mask.

20. The method of claim 19, further comprising forming a lower electrode on a lower surface of the substrate.
